(19) United States
(12) Patent Application Publication
(10) Pub. No.: US 2026/0309260 A1
(43) Pub. Date: Oct. 8, 2026

(54) FLOATING CONNECTOR MECHANISM

(71) Applicant: MELLANOX TECHNOLOGIES, LTD., Yokneam (IL)

(72) Inventors: Adi Caron, Pardesya (IL); Samer Khoury, Nof Haglil (IL); Ron Hartston, Alonei Aba (IL)

(21) Appl. No.: 19/169,852

(22) Filed: Apr. 3, 2025

(51) Int. Cl. F16L 37/40; H05K 7/20

(52) U.S. Cl. CPC F16L 37/40; H05K 7/20272

(57) ABSTRACT

A connector that can be connected between a rack and a switch includes a coupling member, which is connected to a piston assembly that is operatively coupled to a body structure, and a stationary interface member, which is coupled to the body structure. The piston assembly includes a piston connected to the coupling member that can be displaced in both axial and radial directions with respect to the body structure so that the coupling member can move in the axial and radial directions. The connector may be included in a switch.

### FIELD

The present disclosure relates to connector mechanisms, and more particularly, to connector mechanisms for connecting rack-mountable devices to racks.

### BACKGROUND

For liquid-cooled rack-mountable devices (e.g., rack switches and blade servers), insertion into a rack may require “blind mating,” which means that all connections between the rack-mountable devices and the rack must align without visual confirmation, including any quick disconnect connections, e.g., Universal Quick Disconnect (UQD) connections. To accommodate tolerances, connector mechanisms on rack-mountable devices must be able to float and compensate for misalignments, which are achieved by current connector designs. However, in the current connector designs, any movement outside the rack-mountable device causes corresponding movement inside the rack-mountable device through the connector, which is undesirable since movement within the rack-mountable device necessitates that all tubing coupled to the connector to be flexible and capable of moving with the connector during blind mating. Thus, rigid connections cannot be used on the rack-mountable device side of the connector mechanism.

### GENERAL DESCRIPTION

A connector that can be connected between a rack and a switch includes a coupling member, which is connected to a piston assembly that is operatively coupled to a body structure, and a stationary interface member, which is coupled to the body structure. The piston assembly includes a piston connected to the coupling member that can be displaced in both axial and radial directions with respect to the body structure so that the coupling member can move in the axial and radial directions while keeping components connected to the rack or the switch stationary to facilitate the connection. The connector may be included in a switch. The connector can be incorporated in all blind mated liquid cooled switches/servers.

In an embodiment, a connector comprises a stationary interface member coupled to a body structure so that the stationary interface member is stationary with respect to the body structure, and a piston assembly operatively coupled to the body structure and connected to the stationary interface member through the body structure, the piston assembly including a piston connected to a coupling member, the piston being positioned in the piston assembly and configured to be displaced in both axial and radial directions with respect to the body structure so that the coupling member can move in the axial and radial directions.

In an embodiment, a connector connected between a rack and a switch comprises a stationary interface member coupled to a body structure so that the stationary interface member is stationary with respect to the body structure, the stationary interface member being connected to the switch, and a piston assembly operatively coupled to the body structure and connected to the stationary interface member through the body structure. The piston assembly includes a piston connected to a coupling member that is connected to the rack. The piston is positioned in the piston assembly and configured to be displaced in both axial and radial directions with respect to the body structure, thereby allowing an axial and radial floatation on a rack side of the connector, while staying stationary on a switch side of the connector. The connector is thus able to float and compensate for misalignments, to accommodate tolerances.

In an embodiment, a liquid-cooled switch comprises a housing, tubing in the housing for transferring coolant, and a connector with two degrees of freedom, the connector being configured to counteract dependency of motions inside and outside of the switch such that when a part of the connector moves outside of the switch, the tubing in the switch connected to the connector does not move.

Other aspects in accordance with the disclosure will become apparent from the following detailed description, taken in conjunction with the accompanying drawings, illustrated by way of example of the principles of the disclosure.

### BRIEF DESCRIPTION OF THE DRAWINGS

FIG. 1 is a diagram of a computing system in which embodiments of the present disclosure may be implemented.

FIG. 2 is a block diagram of a rack-mountable device in accordance with embodiments of the present disclosure.

FIG. 3 is a block diagram of a rack-mountable device with a device-level cooling system in accordance with an embodiment of the present disclosure.

FIG. 4 is a cutaway perspective view of a connector in accordance with an embodiment of the present disclosure.

FIG. 5 is a cutaway side view of the connector in accordance with an embodiment of the present disclosure.

FIG. 6 is an exploded view of the connector in accordance with an embodiment of the present disclosure.

FIG. 7A is a perspective front view of a mount block of the connector in accordance with an embodiment of the present disclosure.

FIG. 7B is a perspective back view of the mount block of the connector in accordance with an embodiment of the present disclosure.

FIG. 8A is a perspective front view of a piston bore of the connector in accordance with an embodiment of the present disclosure.

FIG. 8B is a cutaway side view of the piston bore of the connector in accordance with an embodiment of the present disclosure.

FIG. 9A is a perspective view of a piston of the connector in accordance with an embodiment of the present disclosure.

FIG. 9B is a cutaway side view of the piston of the connector in accordance with an embodiment of the present disclosure.

FIG. 10A is a perspective view of a closing barb of the connector in accordance with an embodiment of the present disclosure.

FIG. 10B is another perspective view of the closing barb of the connector in accordance with an embodiment of the present disclosure.

FIG. 11A is a perspective view of a lock nut of the connector in accordance with an embodiment of the present disclosure.

FIG. 11B is a cutaway side view of the lock nut of the connector in accordance with an embodiment of the present disclosure.

FIG. 12 is a diagram of a switch with two connectors in accordance with an embodiment of the present disclosure.

FIG. 13 illustrates a computer system, according to at least one embodiment.

FIGS. 14A and 14B illustrates a network architecture in accordance with an embodiment of the disclosure.

FIG. 15 illustrates an example network configuration of components that can be used to implement aspects of various embodiments.

FIG. 16 illustrates an exemplary datacenter that has a cooling system in accordance with an embodiment of the disclosure.

FIG. 17 illustrates a client-server network formed by a plurality of network server computers, which are interlinked, in accordance with an embodiment of the present disclosure.

FIG. 18 illustrates a computer network connecting one or more computing machines in accordance with an embodiment of the present disclosure.

FIGS. 19A-19B illustrate a networked computer system in accordance with different embodiments of the present disclosure.

FIG. 20 illustrates neural network enabled devices that are installed directly in a liquid cooled server rack in accordance with an embodiment of the present disclosure.

FIG. 21A illustrates components of a system that can be utilized by a neural network-enabled approach to liquid cooling of racks at a data center level in accordance with an embodiment of the present disclosure.

FIG. 21B illustrates a system that utilizes a reverse return-based design in accordance with an embodiment of the present disclosure.

FIG. 21C illustrates a control system in accordance with an embodiment of the present disclosure.

Throughout the description, similar reference numbers may be used to identify similar elements.

### DETAILED DESCRIPTION

It will be readily understood that the components of the examples as generally described herein and illustrated in the appended figures could be arranged and designed in a wide variety of different configurations. Thus, the following more detailed description of various examples, as represented in the figures, is not intended to limit the scope of the present disclosure, but is merely representative of various examples. While the various aspects of the examples are presented in drawings, the drawings are not necessarily drawn to scale unless specifically indicated.

The present disclosure may be embodied in other specific forms without departing from its spirit or essential characteristics. The described embodiments are to be considered in all respects only as illustrative and not restrictive. The scope of the disclosure is, therefore, indicated by the appended claims rather than by this detailed description. All changes which come within the meaning and range of equivalency of the claims are to be embraced within their scope.

Reference throughout this specification to features, advantages, or similar language does not imply that all of the features and advantages that may be realized with the present disclosure should be or are in any single example.

Rather, language referring to the features and advantages is understood to mean that a specific feature, advantage, or characteristic described in connection with an example is included in at least one example of the present disclosure. Thus, discussions of the features and advantages, and similar language, throughout this specification may, but do not necessarily, refer to the same example.

Furthermore, the described features, advantages, and characteristics of the disclosure may be combined in any suitable manner in one or more embodiments. One skilled in the relevant art will recognize, in light of the description herein, that the disclosure can be practiced without one or more of the specific features or advantages of a particular embodiment. In other instances, additional features and advantages may be recognized in certain examples that may not be present in all examples of the disclosure.

Reference throughout this specification to “one example”, “an example”, or similar language means that a particular feature, structure, or characteristic described in connection with the indicated example is included in at least one embodiment of the present disclosure. Thus, the phrases “in one example”, “in an example”, and similar language throughout this specification may, but do not necessarily, all refer to the same embodiment.

As explained above, liquid-cooled rack-mountable devices (e.g., rack switches and blade servers) may need connectors that can accommodate misalignments when the rack-mountable devices are inserted into a rack. This is due to the fact that inserting a rack-mountable device into a rack may require “blind mating” where the operator stands in front of the server rack and pushes the server in, ensuring everything lines up perfectly despite manufacturing tolerances. Conventional connectors are designed to float to adjust to these misalignments during such blind mating. Unfortunately, the conventional connectors are designed so that any movement outside the rack-mountable device causes corresponding movement inside the rack-mountable device through these connectors, which necessitates the use of flexible tubing in the rack-mountable device, which in turn limits the types of hoses that can be used and creates challenges in the connection process. This lack in separation of movement, results in the shifting of internal switch components during operation. The movement of the hose inside the switch creates friction, leading to issues when mating the system to the rack. This friction can prevent the hose from properly connecting to the rack.

A connector in accordance with embodiments of the current disclosure is designed to allow the electrical and fluid connections to float to adjust for any misalignments during blind mating of a rack-mountable device and a rack. However, the connector is further designed so that movements outside the rack-mountable device do not cause corresponding movements inside the rack-mountable device through the connector. This decoupling mechanism reduces friction and enables the use of different types of hoses. The connector eliminates the friction issues caused by the movement of the hose inside the switch, ensuring a smoother connection process. In particular, the connector can be connected to a quick disconnect to a rack without disturbing any internal parts of the switch, and without requiring flexible connection inside the switch, allowing separating the quick disconnect movement outside the switch from inside the switch and the motion between rack side and switch/server side. The design of the connector also allows for the possibility of not using any hoses. As an example, the connector may be directly connected to a manifold of a rack-mountable device without any hoses. This configuration of the connector enables the form factor of the connector to be reduced and also allows for a non-concentric design.

Thus, rigid tubing can be used in the rack-mountable device through the use of the connector, which can increase the strength of the tubing used in the rack-mountable device and/or decrease the overall cost of the rack-mountable device.

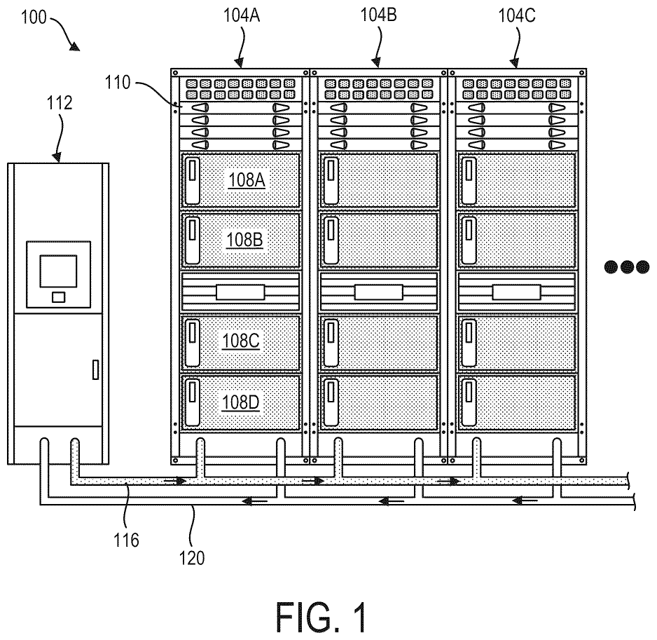

Turning now to FIG. 1, a computing system 100 in which embodiments of the present disclosure may be implemented is shown. In some embodiments, the computing system 100 may include a coolant distribution unit 112 that is capable of supplying coolant via a coolant supply line 116 to one or more server systems 104A-104C. The coolant may be directed to one or more servers 108A-108D and/or one or more switches 110 associated with each of the server systems 104A-104C. Used coolant (e.g., coolant that is heated from cooling the various components of the servers 108A-108D, the switches 110 and/or the server systems 104A-104C) may be returned to the coolant distribution unit 112 via the coolant return line 120, where the used coolant can be cooled and recirculated to the server systems 104A-104C via the coolant supply line 116. In one embodiment, one or more of the server systems 104A-104C may correspond to a rack of DGX™ A100 brand servers and/or a DGX™ brand SuperPod™ manufactured by NVIDIA®. Additionally or alternatively, one or more of the servers 108A-108D may correspond to DGX™ brand servers, and/or the like, manufactured by NVIDIA®.

As can be appreciated, each of the server systems 104A-104C may include additional components, such as power supplies, memory storage devices, cables, cooling lines, and/or the like. In some embodiments, each of the server systems 104A-104C may include a frame, which may be referred to herein as a rack, that is capable of receiving one or more servers 108A-108D and one or more switches 110. The rack of the server systems 104A-104C may be configured as cabinet or other enclosure that includes a plurality of rack units (RU) configured to receive equipment associated with the server systems 104A-104C. The servers 108A-108D and the switches 110 may be designed to be inserted into or mounted to the rack of a server system 104A-104C and may take up one or more RU. Thus, the servers 108A-108D and the switches 110 may be referred to herein as rack-mountable devices.

The coolant distribution unit 112 may comprise at least one pump, heat exchanger, and processor that is capable of controlling the temperature of a coolant directed by the coolant distribution unit 112. In some embodiments, the coolant described herein may correspond to water or any other liquid that is capable of being cooled by the heat exchanger of the coolant distribution unit 112. In one embodiment, the coolant distribution unit 112 may receive a chilled liquid (e.g., water) and/or may include a chiller that is capable of chilling liquid before the coolant is pumped via the coolant supply line 116 to the server systems 104A-104C.

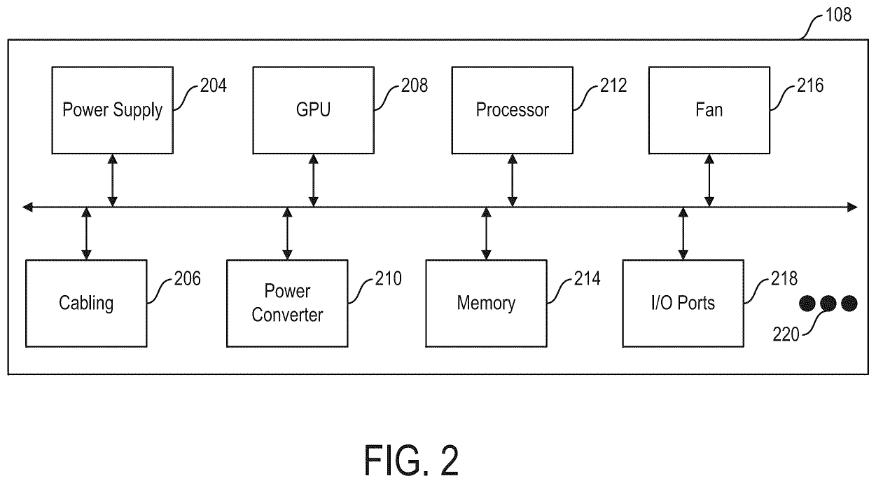

Turning now to FIG. 2, a block diagram of a rack-mountable device 108 in accordance with embodiments of the present disclosure. In FIG. 2, the rack-mountable device 108 is a server, which may correspond to at least one of the servers 108A-108D in the server systems 104A-104C. The server 108 may include a power supply 204, a graphics processing unit (GPU) 208, a power converter 210, a processor 212, a memory 214, a fan 216, I/O ports 218, and/or other components 220. In some embodiments, two or more of the components of the server 108 may be interconnected via cabling 206, an electrical and/or communications bus, electrical traces, electrical interconnections, etc., and/or combinations thereof. These interconnections may be schematically represented by the lines with arrows shown in FIG. 2.

The power supply 204 may provide electrical energy to components of the server 108. In some embodiments, the power supply 204 may include a transformer and/or other electronics that prevent overloading, condition power signals, and/or provide backup power to the server 108.

The GPU 208 may correspond to one or more computer processing devices, processing units, and/or processing circuits. For example, the GPU 208 may be provided as silicon, an Application-Specific Integrated Circuit (ASIC), as a Field Programmable Gate Array (FPGA), any other type of Integrated Circuit (IC) chip, a collection of IC chips, data processing units (DPUs), quantum processing units (QPUs), a plurality of parallel processing units (PPUs), and/or the like. QPUs are configured to perform one or more operations associated with a quantum algorithm. In some embodiments, each of the one or more QPUs may include a plurality of qubits and the one or more QPUs may be in communication with each other via a quantum channel. In some embodiments, each of the plurality of qubits may include local qubits, global qubits, and/or synchronization qubits. In some embodiments, the local qubits of each QPU may be configured to perform the one or more operations associated with the quantum algorithm on the QPU with which the local qubits are associated.

In some examples, the GPU may be provided as a Central Processing Unit (CPU), a microprocessor, or a plurality of microprocessors.

Examples of the GPU 208 may include, but are in no way limited to, the NVIDIA® GeForce® RTX 2000-series processors, NVIDIA® GeForce® RTX 3000-series processors, AMD Radeon™ RX 5000-series processors, AMD Radeon™ RX 6000-series processors, and/or any other graphics processing units.

The power converter 210 may correspond to an electrical circuit or device that is capable of receiving a first voltage (e.g., a first DC voltage) and generating a different second voltage (e.g., a second DC voltage). For example a power converter 210 may convert a first voltage of 8 V into a second voltage of 1 V. Additionally or alternatively, the power converter 210 may include multiple components that generate two different voltages from a first received voltage. In this example, the power converter 210 may convert a first voltage of 54 V into a first different voltage of 8 V and a second different voltage of 1 V. In some embodiments, the power converter 210 may include multiple connected power converters.

The processor 212 may be similar, if not identical, to the GPU 208 described above, or vice versa. In some embodiments, the processor 212 may correspond to one or more computer processing devices, processing units, processing circuits, DSPs, general purpose microprocessors (e.g., Intel® Core™ i3, i5, i7, or i9 processors; Intel® Celeron® processors; Intel® Xeon® processors; Intel® Pentium® processors; AMD Ryzen™ processors; AMD Athlon™ processors; AMD Phenom™ processors; Apple A10 or 10X Fusion processors; Apple A11, A12, A12X, A12Z, or A13 Bionic processors; or any other general purpose microprocessors), GPUs (e.g., NVIDIA® GeForce® RTX 2000-series processors, NVIDIA® GeForce® RTX 3000-series processors, AMD Radeon™ RX 5000-series processors, AMD Radeon™ RX 6000-series processors, or any other GPUs), ASICs, FPGAs, or other equivalent integrated or discrete logic circuitry.

The GPU 208 and/or the processor 212 may be generally referred to herein as a “computing device,” a “GPU,” a “processing circuit,” and/or a “processing unit.” In some embodiments, the GPU 208 and/or the processor 212 may correspond to a CPU, a GPU, an FPGA, an ASIC, and/or the like. Accordingly, the term “XPU” may be used to refer to the GPU 208 and/or the processor 212 and may include any compute architecture and associated structure that is capable of performing processing functions of at least one server 108. In some embodiments, the XPU may be a multipurpose, programmable device that accepts digital data as input, processes the digital data according to instructions stored in its internal memory, and provides results as output. The XPU may implement sequential digital logic as the XPU may have internal memory. As with most microprocessors, the XPU may operate on numbers and symbols represented in the binary numeral system.

The memory 214, or storage memory, may correspond to any type of non-transitory computer-readable medium. In some example implementations, the memory 214 may comprise volatile or non-volatile memory and a controller for the same. Non-limiting examples of the storage memory 214 that may be utilized in the server 108 may include Random Access Memory (“RAM”), Read Only Memory (“ROM”), buffer memory, flash memory, solid-state memory, or variants thereof. Any of these memory types may be considered non-transitory computer memory devices even though the data stored thereby can be changed one or more times.

The fan 216 may correspond to a device that is capable of moving, or directing, air throughout the server 108 and/or across one or more surfaces of components of the server 108. In some embodiments, the fan 216 may include one or more blades that, when rotated (e.g., via an electric motor), cause air to move and flow across the components of the server 108. In some examples, the fan 216 may cause air to flow across a heatsink, or cooling plate, of the server 108. The heatsink may be arranged in thermal contact with one or more of the components of the server 108 (e.g., the GPU 208 and/or the processor 212) that generate heat during operation. As these components generate heat, the heatsink transfers heat away from the components (e.g., by absorbing the heat) and directs at least a portion of the heat to one or more fins or surfaces of the heatsink. The flow of air created by the fan 216 may be caused to pass over the fins or surfaces of the heatsink transferring heat away from the heatsink and into the air. In some embodiments, the air may be caused to exit the server 108. New air may be drawn into the server 108 via operation of the fan 216.

The input/output, or I/O, ports 218 may correspond to one or more interconnections through which the server 108 can receive information and/or communications. Additionally or alternatively, the I/O ports 218 may correspond to one or more interconnections through which the server 108 can transmit information and/or communications. Examples of the I/O ports 218 may include, but are in no way limited to, an Ethernet port, an RJ-11 port, an RJ-45 port, an RS-232 port, a USB port and/or combinations thereof.

Although the rack-mountable device 108 has been described as a server, rack-mountable devices described herein may also be switches or other devices that can be inserted into or mounted to a rack. Thus, the rack-mountable devices 108 described herein are not limited to servers.

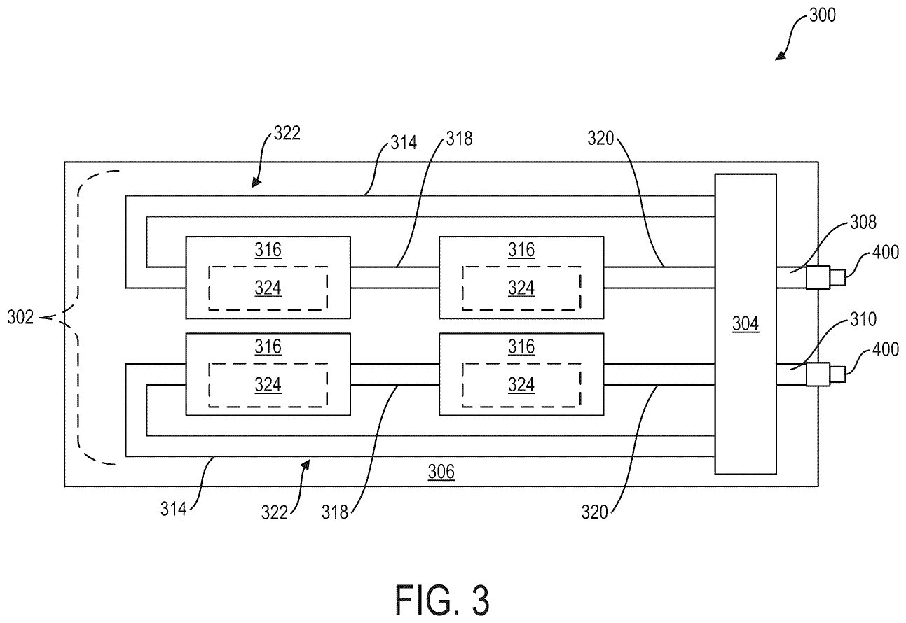

A rack-mountable device, such as the server 108, may be a liquid-cooled device, which includes a device-level cooling system. FIG. 3 illustrates a rack-mountable device 300 with a device-level cooling system 302 in accordance with an embodiment of the disclosure. In the illustrated embodiment, the rack-mountable device 300 is a server. However, in other embodiments, the rack-mountable device 300 may be a different device, such as a switch that can be inserted into a rack. As shown in FIG. 3, the device-level cooling system 302 includes at least one server manifold 304 in a housing 306 to allow entry and egress of heat transfer fluid such as a coolant from a rack to the rack-mountable device 300. Coolant from a rack manifold enters via inlet pipe 308 and exits via outlet pipe 310. Each of the inlet and outlet pipes are connected to a connector 400, which allows the rack-mountable device 300 to be connected to a rack when the rack-mountable device 300 is inserted into the rack. The connectors 400 are described in more detail below.

The inlet and outlet pipes 308 and 310 are connected to the manifold 304. Coolant from the manifold 304 travels from an inlet line 314 through one or more cold plates 316 via at least one intermediate line 318 connecting the cold plates and back to the manifold 304 via a corresponding outlet line 320. This represents at least one cooling loop 322 within the rack-mountable device 300. In the illustrated embodiment, the rack-mountable device 300 includes two cooling loops 322. However, in other embodiments, the rack-mountable device 300 may include a single cooling loop or more than two cooling loops. In at least one embodiment, each of the cold plates 210 is associated with at least one computing component 324, such as a processor or a GPU.

In at least one embodiment, one or more of the cold plates 316 are configurable cold plates.

The connectors 400 allow for the use of various types of hoses, including rigid, flexible, corrugated or welded hoses, without the need to compensate for internal movement, providing greater flexibility in hose selection. In at least one embodiment, there may be multiple intermediate lines, such as the intermediate lines 318, which may be rigid, flexible, corrugated or welded hoses or tubing, in each of the cooling loops 322 in the rack-mountable device 300. In at least one embodiment, fluid adapters may be provided to enable coupling of the lines to the cold plates 316 and/or the manifold 304. These fluid adapters may be sized to the inlet and outlet specifications of the cold plates 316 and the manifold 304. The connector also allows for the possibility of not using any hoses, e.g., the connector may be directly connected to the manifold 304 or one of the cold plates 316.

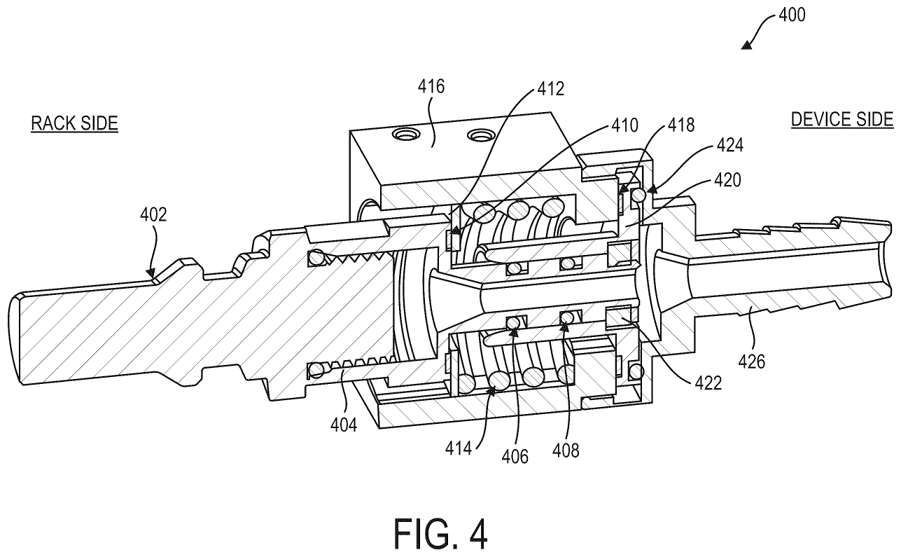

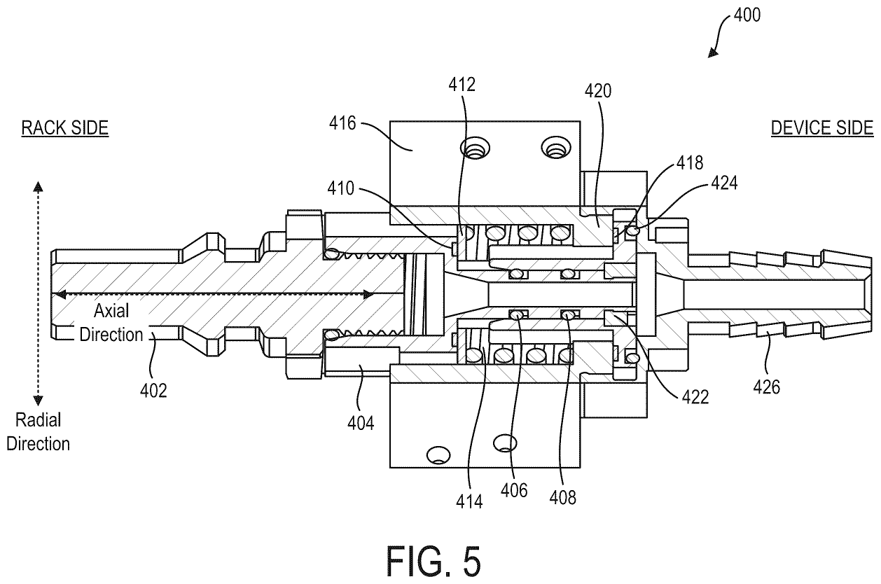

Turning now to FIGS. 4 and 5, a connector 400 in accordance with an embodiment of the disclosure is shown. FIG. 4 is a cutaway perspective view of the connector 400, while FIG. 5 is a cutaway side view of the connector 400. The connector 400 can be used to connect a rack-mountable device, e.g., a server or a switch, to a rack so that the rack-mountable device is physically coupled to the rack. In addition, the connector 400 can be used to provide a fluid connection between the rack-mountable device and the rack so that heat transfer fluid can flow between the rack-mountable device and the rack for liquid-cooling, which involves using a liquid coolant to absorb and dissipate heat from one or more heat-producing components in the rack-mountable device, such as processors and memory modules. In order to more efficiently dissipate the absorbed heat, the liquid coolant is circulated out of the rack-mountable device to a heat exchanger, such as the coolant distribution unit 112. Thus, the connector 400 can be used as a liquid inlet port to supply “cooled” liquid coolant to the rack-mountable device or a liquid outlet port to transfer “heated” liquid coolant out of the rack-mountable device. Thus, in a typical implementation, two of the connectors 400 are used for a single rack-mountable device to transfer liquid coolant into and out of that rack-mountable device.

As shown in FIGS. 4 and 5, the connector 400 includes a stationary interface member 426 coupled to a body structure 416 so that the stationary interface member 426 is stationary with respect to the body structure 416, and a piston assembly 403 operatively coupled to the body structure 416 and operatively coupled to the stationary interface member 426 through the body structure 416.

The piston assembly 403 includes a piston 404 connected to a coupling member 402. The piston 404 is positioned in the piston assembly 403 and is configured to be displaced in both axial and radial directions with respect to the body structure 416 so that the coupling member 402 can move in the axial and radial directions. In some embodiments, the stationary interface member 426 may include a closing barb, or any stationary interface structure that can be attached to a coolant line of a rack-mountable device. In some embodiments, the body structure 416 may be a mount block, or any structure that can be mounted on a rack-mountable device. In some embodiments, the coupling member 402 may be a quick disconnect member 402, or any coupling component that can connect with a corresponding coupling component on a rack. Thus, in this disclosure, the coupling member 402 is sometimes referred to as a quick disconnect member, the body structure 416 is sometimes referred to as a mount block, and the stationary interface member 426 is sometimes referred to as a closing barb.

The quick disconnect member 402 and the closing barb 426 are located on opposite ends of the connector. The quick disconnect member 402 is used to mate with a corresponding quick disconnect member on a rack. As an example, the quick disconnect member 402 may be a Universal Quick Disconnect (UQD) member. In the illustrated embodiment, the quick disconnect member 402 is a male quick disconnect member, which is designed to mate with a female quick disconnect member on a rack. However, in an alternative embodiment, the quick disconnect member 402 may be a female quick disconnect member that is designed to mate with a male quick disconnect member on a rack. In other embodiments, the quick disconnect member 402 can be any coupling member that can connect with a corresponding coupling member on a rack. Since the quick disconnect member 402 is used to connect to the rack, the quick disconnect member is referred to herein as being on the rack side of the connector 400. As described in more detail below, the connector 400 is designed so that the quick disconnect member 402 is a floating component that can move in both axial direction and radial direction (e.g. +/−2mm) allowing bidirectional floatation on the rack side, as illustrated in FIG. 5, to compensate for any misalignment when a rack-mountable device with a pair of the connectors 400 is being inserted into a rack while staying stationary on the device side (e.g., the switch side).

The closing barb 426 of the connector 400 is used to connect to a coolant line in the rack-mountable device to which the connector is attached. The closing barb 426 may be inserted into a coolant line or tubing to provide a fluid connection to a fluid circuiting cooling system in the rack-mountable device, such as the device-level cooling system 302, to cool various components of the rack-mountable device. In other embodiments, the closing barb 426 may be replaced with any stationary interface member that can be attached to a coolant line of a rack-mountable device. Since such interface member would also be attached to the mount block 416, the interface member would also be stationary with respect to the mount block, even when the quick disconnect member 402 experiences any axial and/or radial movements. As an example, the closing barb 426 may be replaced with a metal fitting that can be welded to a rigid or metallic coolant line. Since the closing barb 426 is used to connect to other internal components of a rack-mountable device, the closing barb 426 is referred to herein as being on the device side of the connector 400. As described in more detail below, the connector 400 is designed so that the closing barb 426 is independent of the quick disconnect member movements. In other words, the device side of the connector 400, which may reside in a rack-mountable device, is independent of any movements or motions on the rack side of the connector 400, which refers to motions outside of the rack-mountable device. Specifically, the connector 400 is designed so that the closing barb 426 remains stationary, even when the quick disconnect member 402 is displaced or moved in the axial and/or radial directions. In other words, the connector 400 is designed to counteract dependency of motions inside and outside of a rack-mountable device such that when a part of the connector (e.g., the quick disconnector member 402) moves outside of the rack-mountable device, the tubing in the rack-mountable device connected to the connector does not move. Thus, rigid tubing, e.g., metal tubing, can be used to connect to the closing barb 426 or the device side of the connector, which can reduce the overall cost of the rack-mountable device and can increase the strength of the tubing and associated connections used in the rack-mountable device.

When the quick disconnect member 402 of the connector 400 is mated to a corresponding quick disconnect member on a rack, liquid coolant can flow through the connector. If the connector 400 is being used as an inlet of the rack-mountable device on which the connector is attached, the liquid coolant can flow from the rack to the rack-mountable device. If the connector 400 is being used as an outlet of the rack-mountable device on which the connector is attached, the liquid coolant can flow from the rack-mountable device to the rack. Thus, using two such connectors 400, the liquid coolant can be circulated into and out of the rack-mountable device to regulate the temperature of the various components in the rack-mountable device.

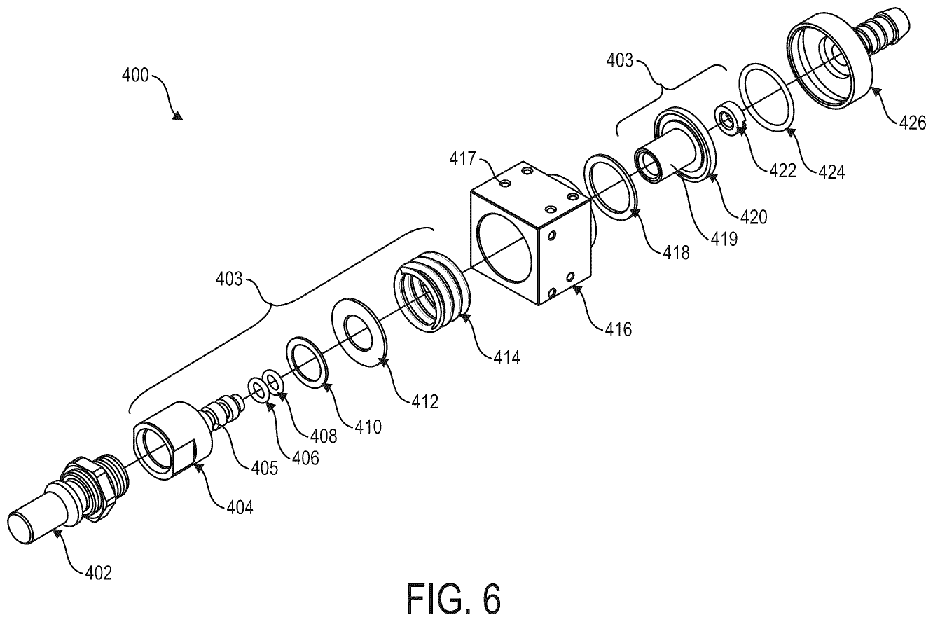

The components of the connector 400 are further described with reference to FIG. 6, which is an exploded view of the connector in accordance with an embodiment of the disclosure. As shown in FIGS. 4-6, the connector 400 includes a mount block 416, which serves as a structural anchor for the other components of the connector. Thus, the other components of the connector 400 are structurally supported by the mount block 416. As such, the mount block 416 can be viewed as being the body of the connector 400. Thus, the mount block 416 may be referred to herein as the body structure. The mount block 416 can be used to physically attach the connector 400 to a rack-mountable device, such as a server or a switch. In the illustrated embodiment, the mount block 416 includes multiple holes 417 for screws to mount the connector 400 to a rack-mountable device.

However, in other embodiments, the mount block 416 may have other types of features that can be used to mount the connector 400 to a rack-mountable device. Alternatively, the mount block 416 may not include any features that can be used to mount the connector to a rack-mountable device. Rather, an external bracket or other means, such as adhesives or solder, may be used to mount the mount block 416 to a rack-mountable device.

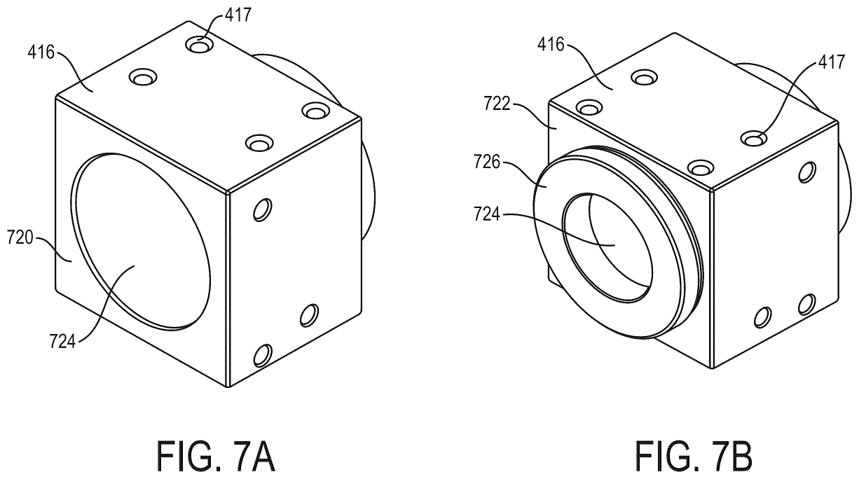

The mount block 416 is illustrated in FIGS. 7A and 7B in more detail. FIG. 7A is a perspective front view of the mount block 416, which shows a front side 720 of the mount block. FIG. 7B is a perspective back view of the mount block 416, which shows a back side 722 of the mount block. As used herein, the front side 720 of the mount block 416 is the side that faces a rack when a rack-mountable device with the connector 400 is being installed in the rack, while the back side 722 of the mount block 416 is the side that faces away from the rack when a rack-mountable device with the connector 400 is being installed in the rack.

The mount block 416 is configured or manufactured to have a central hole 724, which extends through the mount block. Thus, the front side 720 of the mount block 416 includes the front opening of the central hole 724, while the back side 722 of the mount block 416 includes the back opening of the central hole 724. The back side 722 of the mount block 416 further includes a circular protrusion 726, which is used to connect to the closing barb 426.

The piston seals 406 and 408 allow for axial movement and sealing of the heat transfer fluid. A piston 404 and a piston bore member 420, along with the piston seals 406 and 408, enable the quick release member 402 to slide in and out against the spring force. The central hole 724 of the mount block 416 defines an interior region, which is used to accommodate a piston assembly 403, which is connected to the quick disconnect member 402.

In some embodiments, the piston assembly 403 includes a friction-reducing washer 410 and a rigid washer 412 to reduce friction caused by the axial force of the spring. These washers ensure smooth radial movement with minimal force. The piston assembly 403 further includes the piston 404, the piston seals 406 and 408, a coil spring 414, and the piston bore member 420. The piston bore member 420 includes a tubular portion 419, which is designed to receive an elongate portion 405 of the piston 404.

The piston bore member 420 is positioned in the connector 400 so that the piston bore member cannot move in the axial direction. However, the piston 404 is allowed to move in the axial direction, when axial pressure is applied to the piston 404 towards the piston bore member 420 so that the length of the entire piston assembly 403 is reduced. The connector 400 can thus hold pressure during movement.

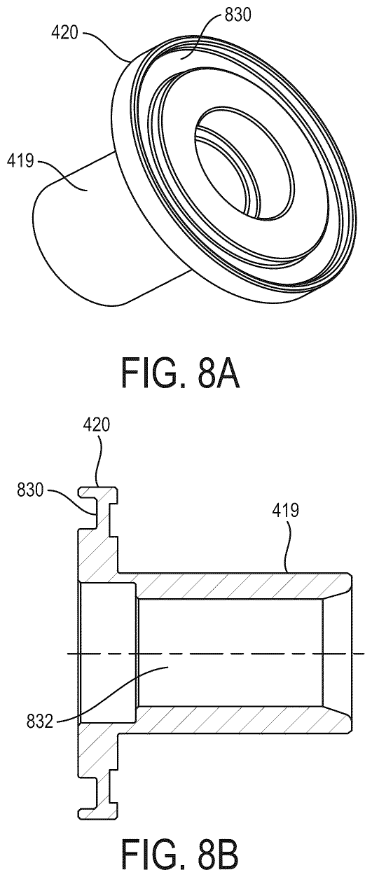

The piston bore member 420 is illustrated in FIGS. 8A and 8B in more detail. FIG. 8A is a perspective view of the piston bore member 420, which shows a circular groove 830 on the backside of the piston bore member. FIG. 8B is a cutaway side view of the piston bore member 420, which shows the interior bore 832 of the tubular portion 419 to accommodate the elongate portion 405 of the piston 404.

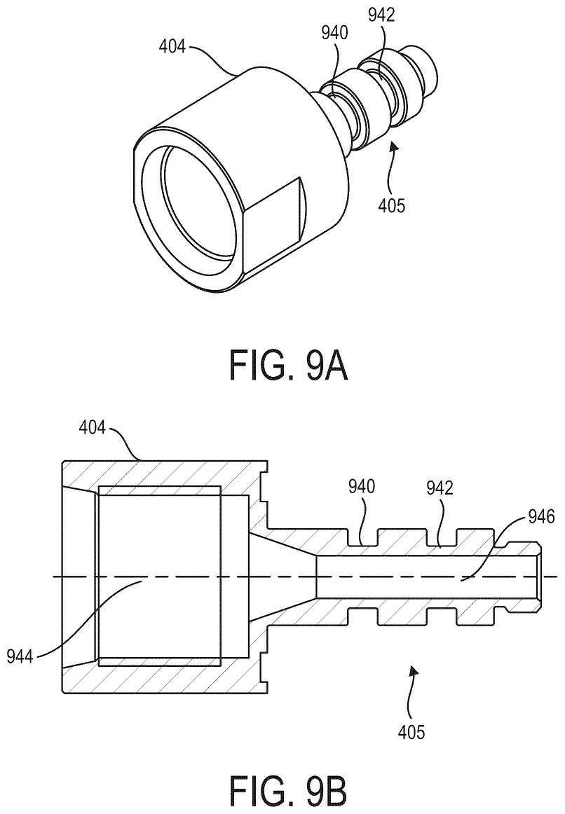

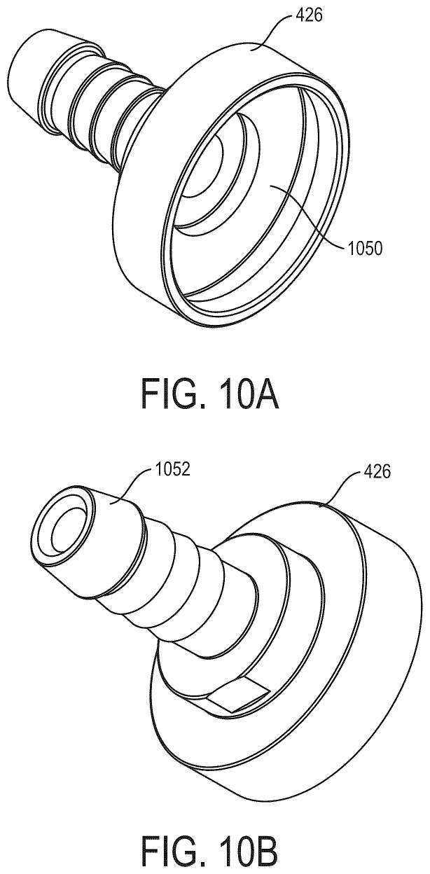

The piston 404 is illustrated in FIGS. 9A and 9B in more detail. FIG. 9A is a perspective view of the piston 404, which shows circular grooves 940 and 942 on the elongate portion 405 of the piston. FIG. 9B is a cutaway side view of the piston 404, which shows a hollow region 944 in a main body of the piston and a hole 946 through the elongate portion of the piston. The hollow region 944 of the piston 404 is used to accommodate the quick release member 402. The hole 946 of the piston 404 is used to allow coolant to flow through the piston.

Turning back to FIGS. 5-7, the quick release member 402 is attached to the piston 404. In the illustrated embodiment, the quick release member 402 is inserted into the hollow region 944 of the piston 404. Since the quick release member 402 is attached to the piston 404, the quick release member is displaced together with the piston. Thus, any movement of the piston 404 causes the same movement on the quick release member 402.

The coil spring 414 of the piston assembly 403 is positioned between the piston bore member 420 and the piston 404 so that the piston with the quick release member 402 is pushed back toward a default position (when the length of the piston assembly is at its maximum length). In an embodiment, the piston bore member 420 and the piston 404 function as a spring preload mechanism with respect to the coil spring 414 to ensure that the piston is returned to its default position, which corresponds to the maximum length of the piston assembly, after any axial movement.

The piston seals 406 and 408 of the piston assembly 403 are positioned on the elongate portion 405 of the piston 404 and are used to ensure a seal is maintained between the piston and the piston bore member 420 to support axial and radial movements while ensuring leak-free coolant flow. The flow is diverted inside the mechanism (and not the whole block moving). This is facilitated by the piston seals 406 and 408 (for axial movement) and a face seal 424 (for radial movement). The seals provide the internal mechanical movement on rack side, while allowing leak free flow.

In particular, the piston seals 406 and 408 are positioned in the circular grooves 940 and 942, respectively, on the elongate portion 405 of the piston 404. In some embodiments, the piston seals 406 and 408 may be O rings, which may be made of a polymer, such as an elastomer.

The friction-reducing washer 410 and the rigid washer 412 of the piston assembly 403 are positioned between the piston 404 and the coil spring 414. The connector 400 further includes another friction-reducing washer 418 positioned between the mount block 416 and the piston bore member 420. As an example, the friction-reducing washers 410 and 418 may be Polytetrafluoroethylene (PTFE) or Teflon washers, and the rigid washer 412 may be a brass washer. The friction-reducing washers 410 and 418 are used to reduce friction when the piston assembly 403 with the quick release member 402 moves along the radial direction.

The connector 400 further includes a lock nut 422, the face seal 424 and the closing barb 426. The closing barb 426 is attached to the mount block 416. Specifically, the closing barb 426 is secured on the circular protrusion 726 of the mount block 416. Since the closing barb 426 is attached to the mount block 416, the closing barb remains stationary with respect to the mount block. When the mount block 416 is installed on a rack-mountable device, the mount block remains stationary with respect to the rack-mountable device, which in turn means that the closing barb 426 also remains stationary with respect to the rack-mountable device. Thus, as noted above, any tubing directly or indirectly connected to the closing barb 426 does not have to be flexible because the tubing will not experience any movement with respect to the rack-mountable device when the quick release member 402 of the connector 400 moves in the axial direction and/or radial direction.

The closing barb 426 is illustrated in FIGS. 10A and 10B in more detail. FIG. 10A is a perspective view of the closing barb 426, which shows an interior region 1050 that is designed to fit on the circular protrusion 726 of the mount block 416. FIG. 10B is another perspective view of the closing barb 426, which shows a barb fitting end 1052 of the closing barb that can be inserted into a tube. It is noted here again that, in other embodiments, the closing barb 426 may be replaced with any interface member that can be attached to a coolant line of a rack-mountable device.

Turning back to FIGS. 5-7, the face seal 424 is positioned between the piston bore member 420 and the closing barb 426 to serve as a seal between the piston assembly 403 and the closing barb 426. In some embodiments, the face seal 424 may be an O ring, which may also be made of a polymer, such as an elastomer, similar to the piston seals 406 and 408. The lock nut 422 fits on the end of the elongate portion 405 of the piston 404, and is used to lock the piston assembly 403 in place, and preload the coil spring 414. The lock nut 422 is also used to determine the axial displacement of the piston 404.

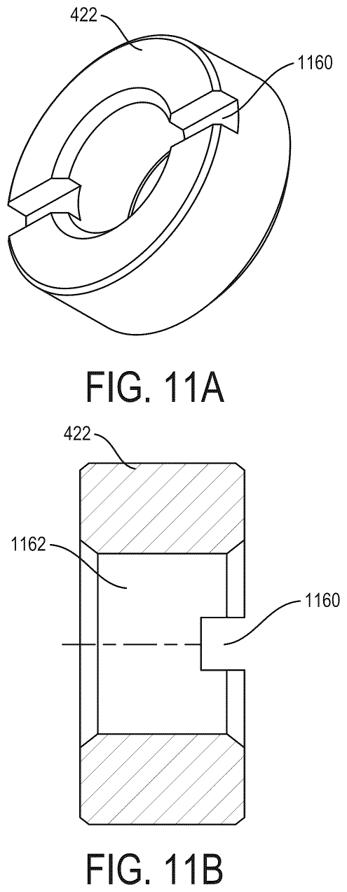

The lock nut 422 is illustrated in FIGS. 11A and 11B in more detail. FIG. 11A is a perspective view of the lock nut 422, which shows grooves 1160. FIG. 11B is a cutaway side view of the lock nut 422, which shows the grooves 1160, as well as a hole 1162 through the lock nut. The grooves 1160 on the lock nut 422 is for a matching tool (not shown), which has notches that insert into the grooves so that the lock nut 422 can be locked.

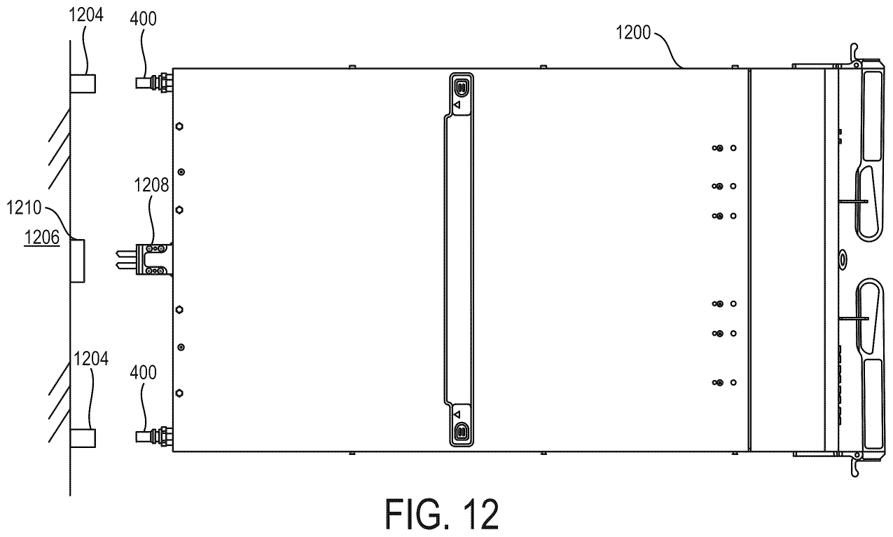

Turning now to FIG. 12, a rack-mountable device 1200 in the form of a switch in accordance with an embodiment of the disclosure is illustrated. As shown in FIG. 12, the rack-mountable device 1200 includes two connectors 400, which can mate with corresponding connectors 1204 on a rack 1206. In some embodiments, each of the connectors 400 of the rack-mountable device 1200 includes a male UQD to connect to a female UQD of the rack connectors 1204 or vice versa. The rack-mountable device 1200 may include one or more other connectors 1208, which can mate with a corresponding connector 1210 on the rack. The connectors 128 may may be used for power and/or communication.

During a process to insert the rack-mountable device 1200 into the rack 1206, there may be axial and/or radial misalignments between the connectors 400 of the rack-mountable device 1200 and the rack connectors 1204. For any radial misalignment, the quick release member 402 (e.g., the UQD) of the connectors 400 may be moved in the radial direction to correct for the misalignment by a radial movement of the piston assembly 403 using the friction-reducing washers 410 and 418. For any axial misalignment, the quick release member 402 (e.g., the UQD) of the connectors 400 may be moved in the axial direction to correct for the misalignment by an axial movement of the piston 404 relative to the piston bore member 420 using the coil spring 414. Thus, the connectors 400 provide two degrees of freedom for the quick release member 402 (e.g., the UQD) of the connectors.

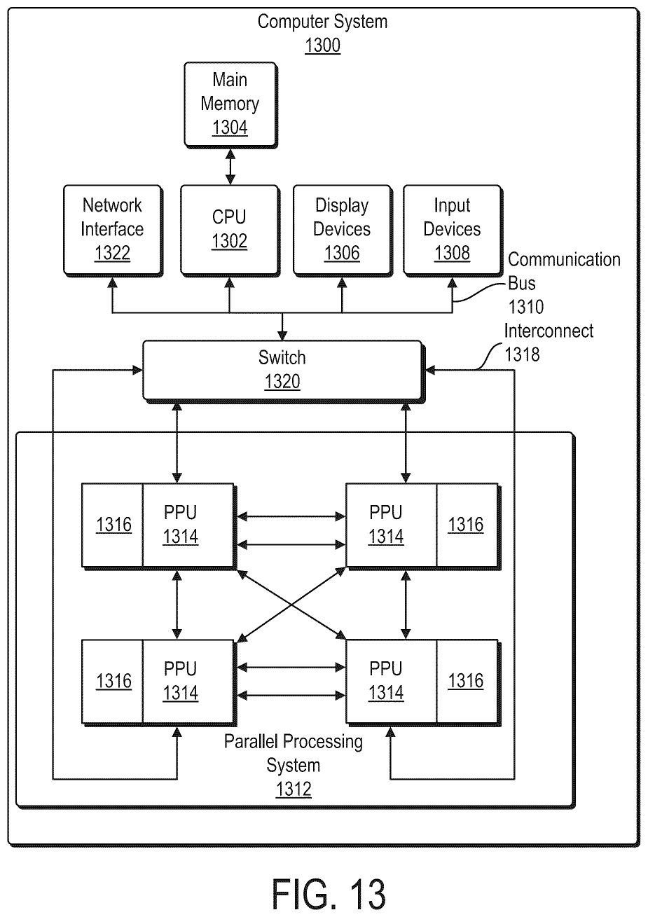

FIG. 13 illustrates a computer system 1300, according to at least one embodiment. In at least one embodiment, computer system 1300 is configured to implement various processes and methods described throughout this disclosure.

In at least one embodiment, computer system 1300 comprises, without limitation, at least one central processing unit (“CPU”) 1302 that is connected to a communication bus 1310 implemented using any suitable protocol, such as PCI (“Peripheral Component Interconnect”), peripheral component interconnect express (“PCI-Express”), AGP (“Accelerated Graphics Port”), HyperTransport, or any other bus or point-to-point communication protocol(s). In at least one embodiment, computer system 1300 includes, without limitation, a main memory 1304 and control logic (e.g., implemented as hardware, software, or a combination thereof) and data are stored in main memory 1304 which may take form of random access memory (“RAM”). In at least one embodiment, a network interface subsystem (“network interface”) 1322 provides an interface to other computing devices and networks for receiving data from and transmitting data to other systems from computer system 1300.

In at least one embodiment, computer system 1300, in at least one embodiment, includes, without limitation, input devices 1308, parallel processing system 1312, and display devices 1306 which can be implemented using a conventional cathode ray tube (“CRT”), liquid crystal display (“LCD”), light emitting diode (“LED”), plasma display, or other suitable display technologies. In at least one embodiment, user input is received from input devices 1308 such as keyboard, mouse, touchpad, microphone, and more. In at least one embodiment, each of foregoing modules can be situated on a single semiconductor platform to form a processing system.

In at least one embodiment, computer programs in form of machine-readable executable code or computer control logic algorithms are stored in main memory 1304 and/or secondary storage. Computer programs, if executed by one or more processors, enable system 1300 to perform various functions in accordance with at least one embodiment. memory 1304, storage, and/or any other storage are possible examples of computer-readable media. In at least one embodiment, secondary storage may refer to any suitable storage device or system such as a hard disk drive and/or a removable storage drive, representing a floppy disk drive, a magnetic tape drive, a compact disk drive, digital versatile disk (“DVD”) drive, recording device, universal serial bus (“USB”) flash memory, etc. In at least one embodiment, architecture and/or functionality of various previous figures are implemented in context of CPU 1302; parallel processing system 1312; an integrated circuit capable of at least a portion of capabilities of both CPU 1302; parallel processing system 1312; a chipset (e.g., a group of integrated circuits designed to work and sold as a unit for performing related functions, etc.); and any suitable combination of integrated circuit(s).

In at least one embodiment, architecture and/or functionality of various previous figures are implemented in context of a general computer system, a circuit board system, a game console system dedicated for entertainment purposes, an application-specific system, and more. In at least one embodiment, computer system 1300 may take form of a desktop computer, a laptop computer, a tablet computer, servers, supercomputers, a smart-phone (e.g., a wireless, hand-held device), personal digital assistant (“PDA”), a digital camera, a vehicle, a head mounted display, a hand-held electronic device, a mobile phone device, a television, workstation, game consoles, embedded system, and/or any other type of logic.

In at least one embodiment, parallel processing system 1312 includes, without limitation, a plurality of parallel processing units (“PPUs”) 1314 and associated memories 1316. In at least one embodiment, PPUs 1314 are connected to a host processor or other peripheral devices via an interconnect 1318 and a switch 1320 or multiplexer. In at least one embodiment, parallel processing system 1312 distributes computational tasks across PPUs 1314 which can be parallelizable—for example, as part of distribution of computational tasks across multiple graphics processing unit (“GPU”) thread blocks. In at least one embodiment, memory is shared and accessible (e.g., for read and/or write access) across some or all of PPUs 1314, although such shared memory may incur performance penalties relative to use of local memory and registers resident to a PPU 1314. In at least one embodiment, operation of PPUs 1314 is synchronized through use of a command such as_syncthreads( ), wherein all threads in a block (e.g., executed across multiple PPUs 1314) to reach a certain point of execution of code before proceeding.

Datacenters and other networking systems may include connections between datacenters, switch systems, servers, racks, and devices in order to provide for signal transmission between one or more of these elements. These connections may be made using cables, transceivers, interconnects, interposers, and connector assemblies. For high bandwidth applications and/or connections over long distances, high powered optical communications may be preferred to ensure signal transmission integrity.

Datacenters may include multiple network switches in a particular topology, such as a fat tree topology, a slim fly topology, a dragonfly topology, multi-level fat-trees, fat-flys, Benes, Clos, meshes, and tori and/or the like. The specifications and makeup of the network switches in the topology affects the overall network performance (e.g., bandwidth capability) of the datacenter.

Datacenters are the storage and data processing hubs of the internet. The massive deployment of cloud applications is causing datacenters to expand exponentially in size, stimulating the development of faster switches than can cope with the increasing data traffic inside the datacenter. Current state-of-the-art switches are capable of handling 12.8 Tb/s of traffic by employing electrical switches in the form of application specific integrated circuits (ASICs) equipped with 256 data lanes, each operating at 50 Gb/s. Such switching ASICs typically consume as much as 400 W, and the power consumption of the optical transceiver interfaces attached to each ASIC is comparable. To keep pace with traffic demand, switch capacity doubles approximately every two years. To date, this rapid scaling has been made possible by exploiting advances in manufacturing (e.g., CMOS techniques), collectively described by Moore's law (i.e., the observation that the number of transistors in a dense integrated circuit doubles about every two years). However, in recent years there are strong indications of Moore's law slowing down, which raises concerns about the capability to sustain the target scaling rate of switch capacity. As a result, alternative technologies are being investigated.

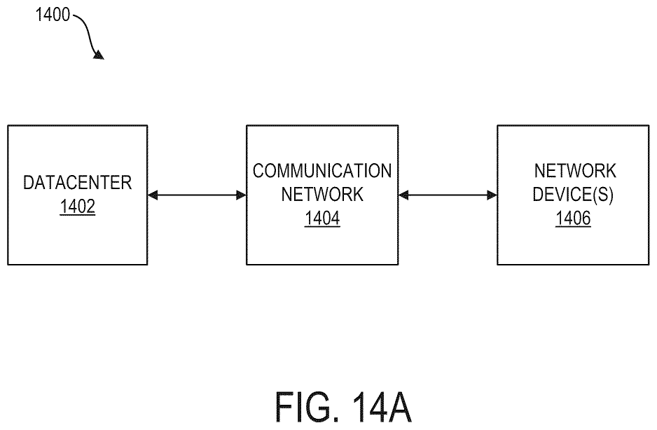

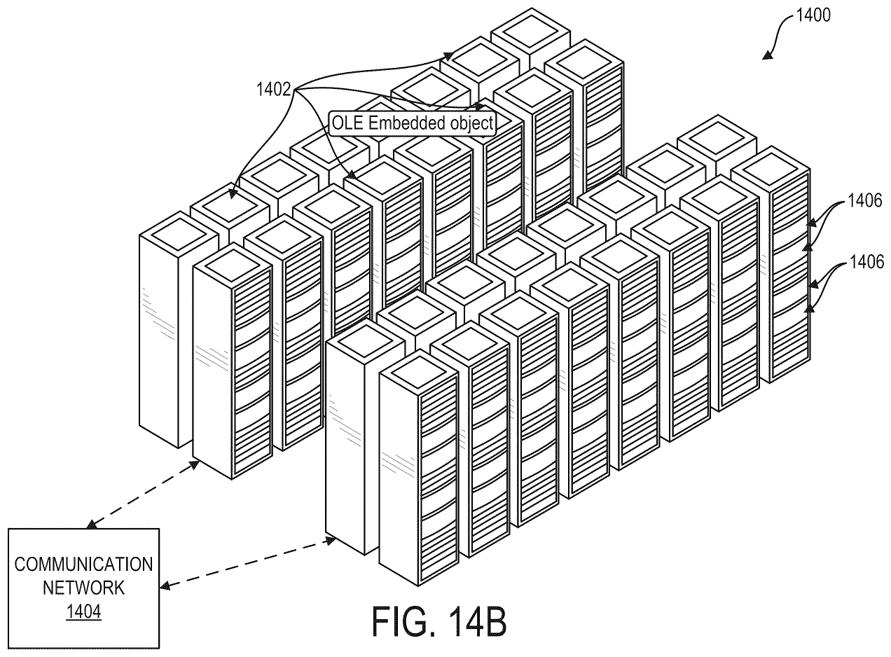

As described above, datacenters, high performance computing clusters, and/or the like are often formed of various computing components or networked devices, and communication networks formed of electrical and/or optical devices may be used to enable communication between the networked devices forming these implementations. With reference to FIGS. 14A-14B, for example, a network architecture 1400 may include a datacenter 1402, a communication network 1404, and network device(s) 1406. The network architecture 1400 may illustrate a general computing architecture within which more specific systems and/or subsystems may function. Although described hereinafter with reference to a network architecture 1400 and/or datacenter 1402 within which the embodiments of the present disclosure may be implemented, the present disclosure contemplates that the transceiver resiliency devices and techniques described herein may be applicable to any communication implementation without limitation.

For example, the datacenter 1402 may be a centralized facility designed to house computing resources and related components. The datacenter 1402 may operate to support the infrastructure required for advanced computational tasks, for efficient, secure, and reliable operations. The datacenter 1402 may include the building and structural components, including power supplies, cooling systems, fire suppression systems, and physical security measures that are configured to maintain optimal operating conditions and/or protect the equipment from environmental hazards and unauthorized access. An example datacenter 1402 may include high-performance servers or compute nodes, often arranged in racks, such as those illustrated in FIG. 14B, and connected through high-speed networks as described herein. These servers may include processors (e.g., central processing units (CPUs), graphics processing units (GPUs), data processing units (DPUs) and/or the like), memory (e.g., RAM), and storage solutions (e.g., hard disk drives (HDDs), solid state drives (SSDs), and/or the like. The hardware configuration may be designed for parallel processing and high throughput, catering to the demands of high-performance computing (HPC) applications.

The datacenter 1402 may include high-speed network equipment, such as network switches, routers, firewalls, and/or the like to facilitate fast and secure data transmission within the datacenter 1402 (e.g., between the servers or compute nodes) and between external networks. The datacenter 1402 may facilitate communication between servers or compute nodes through a network topology that ensures efficient data exchange, minimizes latency, and maximizes bandwidth. The network topology may dictate how various network devices, such as switches and routers, are interconnected for data flow. By implementing an effective network topology, the datacenter 1402 may support high-performance computing tasks. Examples of various network topologies may include hierarchical networking topologies such as the fat tree topology, Slim Fly topology, Dragonfly topology, and/or the like.

The communication network 1404 may communicably couple the datacenter 1402 with network device(s) 1406 and other external devices for data exchange and connectivity. Examples of the communication network 1404 may include an Internet Protocol (IP) network, an Ethernet network, an InfiniBand (IB) network, a Fibre Channel network, the Internet, a cellular communication network, a wireless communication network, combinations thereof (e.g., Fibre Channel over Ethernet), variants thereof, and/or the like. The ability of the communication network 1404 to incorporate multiple network types and configurations may allow the datacenter 1402 to adapt to diverse application needs, from general data communication to specialized HPC tasks. As described herein, the communication network 1404 may leverage various optical components to establish communication links (e.g., communicably couple) between components in the architecture 1400. As such, the communication network 1404 may include various optical devices, transceivers, modules, and/or the like that are configured to generate optical signals (e.g., provide optical transmitter functionality) and/or receive optical signals (e.g., provide optical receiver functionality).

The network device(s) 1406 may include a variety of computing devices capable of transmitting and receiving signals over the communication network 1404. The network device(s) 1406 may range from personal computing devices to complex server configurations. Examples include Personal Computers (PCs), laptops, tablets, smartphones, and servers. The network device(s) 1406 may facilitate user interactions with the datacenter 1402, allowing for data input, retrieval, and processing from remote locations. In addition to individual computing devices, the network device(s) 1406 may also include collections of servers or additional datacenters. For instance, these could be other datacenters similar to or the same as datacenter 1402. Such an interconnection may allow for the formation of a distributed computing environment for improved redundancy, load balancing, and disaster recovery capabilities. By linking multiple datacenters, the network architecture 1400 may leverage geographically dispersed resources, optimizing performance and ensuring high availability.

As described herein, the datacenter 1402 and/or the network device(s) 1406 may include storage devices and processing circuitry for executing computing tasks, such as controlling the flow of data internally and over the communication network 1404. The processing circuitry may include software, hardware, or a combination thereof. For example, the processing circuitry may include a memory containing executable instructions and a processor (e.g., a microprocessor) that executes these instructions. The memory may correspond to any suitable type of memory device or collection of memory devices configured to store instructions. Non-limiting examples of suitable memory devices include Flash memory, Random Access Memory (RAM), Read Only Memory (ROM), variants thereof, combinations thereof, or similar technologies. In specific embodiments, the memory and processor may be integrated into a common device, such as a microprocessor with integrated memory. Additionally, or alternatively, the processing circuitry may comprise hardware components, such as an application-specific integrated circuit (ASIC). Other non-limiting examples of processing circuitry include Integrated Circuit (IC) chips, CPUs, GPUS, microprocessors, Field Programmable Gate Arrays (FPGAs), collections of logic gates or transistors, resistors, capacitors, inductors, and diodes. Some or all of the processing circuitry may be provided on a Printed Circuit Board (PCB) or a collection of PCBs. It should be appreciated that any appropriate type of electrical component or collection of electrical components may be suitable for inclusion in the processing circuitry.

In addition, although not explicitly shown, the present disclosure contemplates that the datacenter 1402 and network device(s) 1406 may include one or more communication interfaces for facilitating wired and/or wireless communication between one another and other unillustrated elements of the network architecture 1400. These communication interfaces may include a variety of technologies, including but not limited to Ethernet ports, fiber optic connections, Wi-Fi® transceivers, Bluetooth® modules, and cellular communication modules for integration and interoperability among the various components within the network architecture 1400.

Furthermore, the present disclosure contemplates that the network architecture 1400 may include additional components and functionalities. For example, the network architecture may include, without limitation, additional processing units, specialized accelerators (such as Tensor Processing Units or TPUs), enhanced security modules, and redundant power supplies. The inclusion of these elements may be intended to ensure that the network architecture 1400 is robust, scalable, and capable of meeting diverse operational requirements. Any variations, modifications, or adaptations of the described elements that fall within the spirit and scope of the disclosure are considered to be encompassed by the present disclosure. This includes any combinations, sub-combinations, or enhancements of the various described elements to achieve improved performance, reliability, and efficiency in the network architecture 1400.

In high-capacity datacenter networks, such as those illustrated in FIGS. 14A-14B, the communication network 1404 may leverage optical transceivers that transmit and receive optical signals over optical fibers or other optical communication mediums in order to establish connection between devices in the architecture 1400.

In at least one example embodiment, the datacenter 1402 corresponds to a collection of network devices, such as network switches (e.g., Ethernet switches, IP routers, multiservice platforms, various transmission network elements, legacy communication equipment, or in any other suitable communication system) connected with a collection of servers or compute nodes.

A switch fabric serves to transfer the data between the switch ports. A switch fabric comprises one or more interconnect circuits, which may be arranged in various switch fabric architectures, e.g., m*m crossbar, Banyan, Benes, Omega, Clos, multi-plane, STS, TST, shared memory, buffered crossbar, any other suitable blocking or non-blocking architecture, or any applicable mixed architecture thereof. A switch fabric is realized in typical embodiments by hardware, which may comprise Field-Programmable Gate Arrays (FPGAs) and/or Application-Specific Integrated Circuits (ASICs), and in some implementations also bus interconnects. The datacenter 1402 may adhere to a networking topology (e.g., a hierarchal networking topology), such as a fat tree topology, a Slim Fly topology, a Dragonfly topology, and/or the like. The datacenter 1402 routes traffic amongst the network switches and servers therein, and at least one layer of the topology in the datacenter 1402 is coupled to the communication network 1404 to allow networking traffic to flow between the datacenter 1402 and the network device(s) 1406.

The communication network 1404 may communicably couple the datacenter 1402 with network device(s) 1406 and other external devices for data exchange and connectivity. Examples of the communication network 1404 may include an Internet Protocol (IP) network, an Ethernet network, an InfiniBand (IB) network, a Fibre Channel network, the Internet, a cellular communication network, a wireless communication network, combinations thereof (e.g., Fibre Channel over Ethernet), variants thereof, and/or the like.

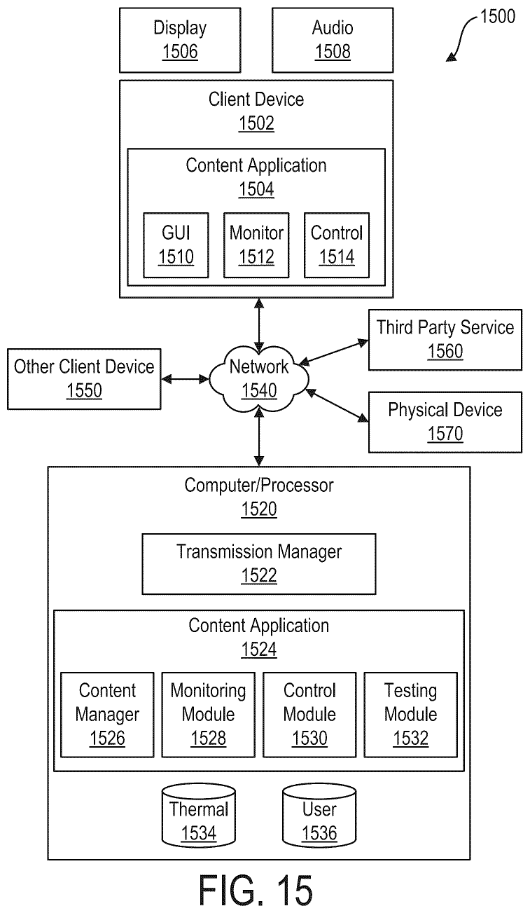

FIG. 15 illustrates an example network configuration 1500 of components that can be used to implement aspects of various embodiments, such as to provide, generate, modify, encode, process, fuse, and/or transmit generated image data, calculated measurements, or other such content. In at least one embodiment, a client device 1502 can generate or receive data for a session using components of a content application 1504 on the client device 1502 and data stored locally on that client device. In at least one embodiment, a content application 1524 executing on a computer or processor 1520 (e.g., a cloud server or control system) may initiate a session associated with at least one client device 1502 (e.g., a vehicle or robot), as may use a session manager and user data stored in a user database 1536, and can cause content such as liquid coolant or server thermal data to be selected and/or retrieved from a repository 1534 to be used by a testing module 1532 to calculate one or more performance metrics for a monitoring module 1528, which can provide flow data or thermal data to a control module 1530 to control a flow or temperature, in an environment where the data is to be used to determine appropriate operation. A content manager 1526 may work with at these various modules to perform testing and analysis, and potentially instruct any actions to be taken in response to a performance metric failing to satisfy an operational requirements. At least a portion of this data or instructional content can be transmitted to the client device 1502 and/or a physical device 1570 using an appropriate transmission manager 1522 to send by download, streaming, or another such transmission channel. An encoder may be used to encode and/or compress at least some of this data before transmitting to the client device 1502.

In at least one embodiment, the client device 1502 receiving such content can provide this content to a corresponding content application 1504, which may also or alternatively include a graphical user interface 1510, a flow monitor module 1512, and a control module 1514 for use in providing, synthesizing, rendering, compositing, modifying, or using content for presentation, navigation, control, (or other purposes) on or by the client device 1502, such as may be transmitted to the physical device 1570. In some embodiments, the computer/processor 1520 and client device 1502 may be able to communicate directly without needing to transmit data over a network 1540, in order to avoid issues with latency and availability, etc. A decoder may also be used to decode data received over the network 1540 for presentation via client device 1502, such as imaging content or performance metrics through a display device 1506 and audio, such as corresponding sounds or synthesized speech, through at least one audio playback device 1508, such as speakers or headphones. In at least one embodiment, at least some of this content may already be stored on, rendered on, or accessible to client device 1502 such that transmission over a network 1540 is not required for at least that portion of content, such as where that content (e.g., thermal data) may have been previously downloaded or stored locally on a hard drive or optical disk. In at least one embodiment, a transmission mechanism such as data streaming can be used to transfer this content from the computer/processor 1520, or user database 1536, to the client device 1502. In at least one embodiment, at least a portion of this content can be obtained, enhanced, and/or streamed from another source, such as a third party service 1560 or other client device 1550, that may also include a content application for generating, updating, enhancing, or providing map content. In at least one embodiment, portions of this functionality can be performed using multiple computing devices, or multiple processors within one or more computing devices, such as may include a combination of CPUs and GPUs (Graphics Processing Unit).

In at least some of these examples, client devices can include any appropriate computing devices, as may include a desktop computer, notebook computer, set-top box, streaming device, gaming console, smartphone, tablet computer, VR headset, AR goggles, wearable computer, or a smart television.

Each client device can submit a request across at least one wired or wireless network, as may include the Internet, an Ethernet, a local area network (LAN), or a cellular network, among other such options. In this example, these requests can be submitted to an address associated with a cloud provider, who may operate or control one or more electronic resources in a cloud provider environment, such as may include a data center or server farm. In at least one embodiment, the request may be received or processed by at least one edge server, that sits on a network edge and is outside at least one security layer associated with the cloud provider environment. In this way, latency can be reduced by allowing the client devices to interact with servers that are in closer proximity, while also improving security of resources in the cloud provider environment.

In at least one embodiment, such a system can be used for monitoring or managing thermal conditions of a server which includes cold plates as liquid manifolds. In other embodiments, such a system can be used for other purposes, such as for providing control of liquid coolant flow, or for performing deep learning operations. In at least one embodiment, such a system can be implemented using an edge device or may incorporate one or more Virtual Machines (VMs). In at least one embodiment, such a system can be implemented at least partially in a data center or at least partially using cloud computing resources.

In at least one embodiment, a cold plate includes adjustable fins forming microchannels for heat transfer fluid to flow through. In at least one embodiment, fins in a cold plate enable transfer of heat from at least one associated computing device to a heat transfer fluid flowing through microchannels formed between multiple fins. In at least one embodiment, fins of a cold plate are dynamically and adjustable in real time to allow transfer of more heat from at least one computing device to a heat transfer fluid that flows through a cold plate having fins. In at least one embodiment, such fins may be adjusted by a processor or processorless system based in part on a temperature determined, such as sensed, for a cold plate. In at least one embodiment, a temperature may be associated with at least one computing device, a workload of at least one computing device, or a heat transfer fluid at different time periods and at an entry, and at an egress of a cold plate. In at least one embodiment, a processorless system may rely on a thermal property of at least two materials used to form fins for a cold plate so that such fins may react without a processor to cause exposure of more surface area to a heat transfer fluid. In at least one embodiment, such fins may include an overlapping portion that may be caused to be exposed by action of a control mechanism or by properties of at least two materials associated together to form a fin.

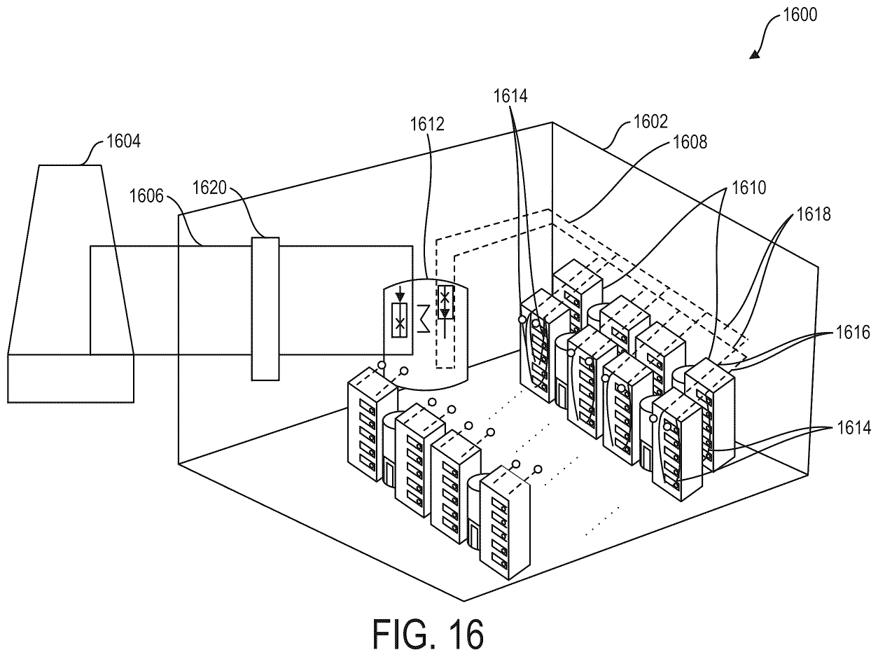

In at least one embodiment, an exemplary datacenter 1600 can be utilized as illustrated in FIG. 16, which has a cooling system subject to improvements described herein. In at least one embodiment, numerous specific details are set forth to provide a thorough understanding, but concepts herein may be practiced without one or more of these specific details. In at least one embodiment, datacenter cooling systems can respond to sudden high heat requirements caused by changing computing-loads in present day computing components. In at least one embodiment, as these requirements are subject to change or tend to range from a minimum to a maximum of different cooling requirements, these requirements must be met in an economical manner, using an appropriate cooling system. In at least one embodiment, for moderate to high cooling requirements, liquid cooling system may be used. In at least one embodiment, high cooling requirements are economically satisfied by localized immersion cooling. In at least one embodiment, these different cooling requirements also reflect different heat features of a datacenter. In at least one embodiment, heat generated from these components, servers, and racks are cumulatively referred to as a heat feature or a cooling requirement as cooling requirement must address a heat feature entirely.

In at least one embodiment, a datacenter liquid cooling system is disclosed. In at least one embodiment, this datacenter cooling system addresses heat features in associated computing or datacenter devices, such as in graphics processing units (GPUs), in switches, in dual inline memory module (DIMMs), or central processing units (CPUs). In at least one embodiment, these components may be referred to herein as high heat density computing components.

Furthermore, in at least one embodiment, an associated computing or datacenter device may be a processing card having one or more GPUs, switches, or CPUs thereon. In at least one embodiment, each of GPUs, switches, and CPUs may be a heat generating feature of a computing device. In at least one embodiment, a GPU, a CPU, or a switch may have one or more cores, and each core may be a heat generating feature.

In at least one embodiment, a cold plate includes adjustable fins forming microchannels for heat transfer fluid to flow through. In at least one embodiment, fins in a cold plate enable transfer of heat from at least one associated computing device to a heat transfer fluid flowing through microchannels formed between multiple fins. In at least one embodiment, fins of a cold plate are dynamically and adjustable in real time to allow transfer of more heat from at least one computing device to a heat transfer fluid that flows through a cold plate having fins. In at least one embodiment, such fins may be adjusted by a processor or processorless system based in part on a temperature determined, such as sensed, for a cold plate. In at least one embodiment, a temperature may be associated with at least one computing device, a workload of at least one computing device, or a heat transfer fluid at different time periods and at an entry, and at an egress of a cold plate. In at least one embodiment, a processorless system may rely on a thermal property of at least two materials used to form fins for a cold plate so that such fins may react without a processor to cause exposure of more surface area to a heat transfer fluid. In at least one embodiment, such fins may include an overlapping portion that may be caused to be exposed by action of a control mechanism or by properties of at least two materials associated together to form a fin.

In at least one embodiment, a cold plate has a top plate, a bottom plate, and fins in between. In at least one embodiment, a bottom plate may be a base of a cold plate. In at least one embodiment, a top plate may be intermediary between a cover plate of a cold plate and a bottom or base plate of a cold plate. In at least one embodiment, fins may be coupled to a bottom or base plate and to a top plate so that a top plate may be moved to uncover an overlapping portion of each fin and expose an overlapping portion of each fin to heat transfer fluid flowing through a cold plate. In at least one embodiment, exposure of an overlapping portion of each fin results in surface area previously covered to be exposed to heat transfer fluid and to provide additional cooling of fins of a cold plate, and by association, of an associated computing device.

In at least one embodiment, multiple fins form microchannels for heat transfer fluid to flow therebetween. In at least one embodiment, such fins are able to actively or passively react to thermal feedback by a modification of microchannels to enable heat transfer fluid to absorb more heat from at least one computing device. In at least one embodiment, an active reaction may be enabled by at least one processor that can expose more surface area of such fins by expanding an overlapping portion of such fins. In at least one embodiment, a passive reaction may be enabled by a thermal property of materials associated together to form each fin of such fins that allows such fins to expand.

In at least one embodiment, issues of cold plates being static devices are addressed by intelligent and dynamic cold plates herein. In at least one embodiment, an intelligent and dynamic cold plate allows a cold plate (via its internal features) to react to sensed or determined temperature from at least one computing device. In at least one embodiment, compared to static cold plates, intelligence aspects of an intelligent and dynamic cold plate allow sensor inputs to be used to modify provided fins of such a cold plate. In at least one embodiment, microchannels formed by such fins are able to be changed to cause a change in a fluid path or to increase interaction surfaces between a heat transfer fluid and each such fin. In at least one embodiment, such aspects allow more heat transfer fluid to pass through to certain areas or to pass through certain areas and allow heat removal in those areas where high heat density occurs from at least one computing device.

In at least one embodiment, static cold plates used for liquid cooling of GPU, CPU, Switches, and other high heat density components may have static microchannels allowing flow of heat transfer fluid therein to remove heat from such heat dissipating components in datacenters. In at least one embodiment, static cold plates incorporate design and methods for heat removal that are not related to or reactive to heat density or heat dissipation by computing components. In at least one embodiment, some cold plates may have varying thermal behaviors depending on computational, environmental and other attributes that require a dynamic behavior for achieving optimum heat removal capability for available resources in a liquid cooled environment.

In at least one embodiment, an indirect cooling cold plate, which is liquid-cooled, may be composed of parts therein. In at least one embodiment, two parts may be provided so that a bottom or base layer or part provides a rigid mechanical attachment and also works as a highly thermal conductive medium where heat is conducted from computing components (GPU, Switch, and CPU) to multiple fins forming microchannels over a bottom or base plate or part. In at least one embodiment, such fins are built into a base metal and may be associated with a top or upper plate or part, which is an intermediary plate or part. In at least one embodiment, a top or upper plate or part that is an intermediary plate or part is non-conductive and made of a non-conductive material. In at least one embodiment, a cover plate encloses (with side plates) such parts within an intelligent and dynamic cold plate.

In at least one embodiment, a top or upper plate or part, by its intermediary plate or part function, is able to dynamically modify a base plate's microchannel fluid path based in part on an instantaneous thermal behavior of heating components associated with an intelligent and dynamic cold plate. In at least one embodiment, using intelligent sensing, inferencing and adaptive modification, microchannels forming fluid paths may be dynamically adjusted to cause or rush more heat transfer fluid (for heat removal) to areas of high heat density within an intelligent and dynamic cold plate. In at least one embodiment, such features also enable simultaneous reduction of fluids flow to block microchannels for areas where there is less demand for heat removal determined or sensed from a base plate of an intelligent and dynamic cold plate. In at least one embodiment, an overlapping portion of provided fins within an intelligent and dynamic cold plate may be used to block or restrict microchannels by being thicker at an overlapping portion between fins of an intelligent and dynamic cold plate. In at least one embodiment, multiple top plates may be provided to function as intermediary plates and may each be associated with different fins. In at least one embodiment, movement of different top plates achieve different blocks or restrictions or flow redirection within an intelligent and dynamic cold plate.

In at least one embodiment, an exemplary datacenter 1600 can be utilized as illustrated in FIG. 16, which has a cooling system subject to improvements described herein. In at least one embodiment, a datacenter 1600 may be one or more rooms 1602 having racks 1610 and auxiliary equipment to house one or more servers on one or more server trays. In at least one embodiment, a datacenter 1600 is supported by a cooling tower 1604 located external to a datacenter 1600. In at least one embodiment, a cooling tower 1604 dissipates heat from within a datacenter 1600 by acting on a primary cooling loop 1606. In at least one embodiment, a cooling distribution unit (CDU) 1612 is used between a primary cooling loop 1606 and a second or secondary cooling loop 1608 to enable absorption of heat from a second or secondary cooling loop 1608 to a primary cooling loop 1606. In at least one embodiment, a secondary cooling loop 1608 can access various plumbing into a server tray as required, in an aspect. In at least one embodiment, loops 1606, 1608 are illustrated as line drawings, but a person of ordinary skill would recognize that one or more plumbing features may be used. In at least one embodiment, flexible polyvinyl chloride (PVC) pipes may be used along with associated plumbing to move heat transfer fluid along in each provided loop 1606; 1608. In at least one embodiment, one or more coolant pumps may be used to maintain pressure differences within coolant loops 1606, 1608 to enable movement of coolant according to temperature sensors in various locations, including in a room, in one or more racks 1610, and/or in server boxes or server trays within one or more racks 1610.

In at least one embodiment, coolant in a primary cooling loop 1606 and in a secondary cooling loop 1608 may be at least water and an additive. In at least one embodiment, an additive may be glycol or propylene glycol. In operation, in at least one embodiment, each of a primary and a secondary cooling loops may have their own coolant. In at least one embodiment, coolant in secondary cooling loops may be proprietary to requirements of components in a server tray or in associated racks 1610. In at least one embodiment, a CDU 1612 is capable of sophisticated control of coolants, independently or concurrently, within provided coolant loops 1606, 1608. In at least one embodiment, a CDU may be adapted to control flow rate of coolant so that coolant is appropriately distributed to absorbed heat generated within associated racks 1610. In at least one embodiment, more flexible tubing 1614 is provided from a secondary cooling loop 1608 to enter each server tray to provide coolant to electrical and/or computing components therein.

The heat transfer fluid generally includes water, water solutions (e.g. propylene glycol-water), brine, antifreeze, a mixture of antifreeze and water, oil, alcohol, mercury or the like or any other suitable heat conductive fluid. The heat transfer fluid may be an electrically conductive cooling liquid and may include water, deionized water, or a coolant such as R-134a, a mixture of water and additives, such as a mixture of water and ethylene glycol or a mixture of water and propylene glycol e.g. a 25% concentration of propylene glycol in deionized water. The heat transfer fluid may also be a dielectric fluid alone (e.g., not having water for purposes of this disclosure) or a water in combination with an additive including at least one dielectric fluid, such as or one or more of de-ionized water, ethylene glycol, and propylene glycol. In at least one embodiment, the heat transfer fluid may be an absorption chiller having a working fluid being a mixed solution containing lithium bromide as the absorbent material and water as the carrier material. The heat transfer fluid may also be a two-phase coolant that has a boiling point that is below the expected operating temperature of the electronic devices. Exemplary two-phase coolants include 2, 3, 3, 3-tetrafluoropropene, 1, 1, 1, 2-tetrafluoroethane and water.

In at least one embodiment, tubing 1618 that forms part of a secondary cooling loop 1608 may be referred to as room manifolds. Separately, in at least one embodiment, further tubing 1616 may extend from row manifold tubing 1618 and may also be part of a secondary cooling loop 1608 but may be referred to as row manifolds. In at least one embodiment, coolant tubing 1614 enters racks as part of a secondary cooling loop 1608 but may be referred to as rack cooling manifold within one or more racks. In at least one embodiment, row manifolds 1616 extend to all racks along a row in a datacenter 1600. In at least one embodiment, plumbing of a secondary cooling loop 1608, including coolant manifolds 1618, 1616, and 1614 may be improved by at least one embodiment herein. In at least one embodiment, a chiller 1620 may be provided in a primary cooling loop within datacenter 1602 to support cooling before a cooling tower. In at least one embodiment, additional cooling loops that may exist in a primary control loop and that provide cooling external to a rack and external to a secondary cooling loop, may be taken together with a primary cooling loop and is distinct from a secondary cooling loop, for this disclosure.

In at least one embodiment, in operation, heat generated within server trays of provided racks 1610 may be transferred to a coolant exiting one or more racks 1610 via flexible tubing of a row manifold 1614 of a second cooling loop 1608. In at least one embodiment, second coolant (in a secondary cooling loop 1608) from a CDU 1612, for cooling provided racks 1610, moves towards one or more racks 1610 via provided tubing. In at least one embodiment, second coolant from a CDU 1612 passes from on one side of a room manifold having tubing 1618, to one side of a rack 1610 via a row manifold 1616, and through one side of a server tray via different tubing 1614. In at least one embodiment, spent or returned second coolant (or exiting second coolant carrying heat from computing components) exits out of another side of a server tray (such as enter left side of a rack and exits right side of a rack for a server tray after looping through a server tray or through components on a server tray). In at least one embodiment, spent second coolant that exits a server tray or a rack 1610 comes out of different side (such as exiting side) of tubing 1614 and moves to a parallel, but also exiting side of a row manifold 1616. In at least one embodiment, from a row manifold 1616, spent second coolant moves in a parallel portion of a room manifold 1618 and is going in an opposite direction than incoming second coolant (which may also be renewed second coolant), and towards a CDU 1612.

In at least one embodiment, spent second coolant exchanges its heat with a primary coolant in a primary cooling loop 1606 via a CDU 1612. In at least one embodiment, spent second coolant may be renewed (such as relatively cooled when compared to a temperature at a spent second coolant stage) and ready to be cycled back to through a second cooling loop 1608 to one or more computing components. In at least one embodiment, various flow and temperature control features in a CDU 1612 enable control of heat exchanged from spent second coolant or flow of second coolant in and out of a CDU 1612. In at least one embodiment, a CDU 1612 may be also able to control a flow of primary coolant in primary cooling loop 1606.

In an embodiment, the switches may be 1U switches, where “1U” refers to the industry-standard size for rack-mounted switches and servers. The switches may be electrical switches, optical switches, hybrid electro-optical switches, or any combination thereof. The switches may be implemented with suitable hardware and/or software that enables the routing of signals in the appropriate domain. For example, an electrical switch may include receivers that receive and convert optical signals into electrical signals for routing within the electrical switch. A receiver of an electrical switch may include a transimpedance amplifier (TIA), a photodetector, and a controller which all serve to convert the optical signals into electrical signals. Each electrical switch may further include transmitters that convert electrical signals routed within the electrical switch into optical signals for output to another switch (optical or electrical) within the system. For example, a transmitter of an electrical switch may include a light source, a modulator, and a controller that controls the modulator and light source. In some embodiments, receiver/transmitter pairs may be integrated into a single transceiver. Each electrical switch may also include internal switching circuitry for routing electrical signals within the electrical switch.

Throughout the instant description, the terms “electrical switch,” “electrical switching ASIC,” “ASIC,” and variants thereof are used interchangeably. Although the electrical switches may be embodied by ASICs, example embodiments are not limited thereto, and the electrical switches may be implemented with any suitable hardware and/or software that enables routing of signals in the electrical domain.

For example, an electrical switch may include receivers that receive and convert optical signals into electrical signals for routing within the electrical switch. For example, a receiver of an electrical switch may include a transimpedance amplifier (TIA), a photodetector, and a controller which all serve to convert the optical signals into electrical signals. Each electrical switch may further include transmitters that convert electrical signals routed within the electrical switch into optical signals for output to another switch (optical or electrical) within the system. For example, a transmitter of an electrical switch may include a light source, a modulator, and a controller that controls the modulator and light source. In at least one example embodiment, receiver/transmitter pairs are integrated into a single transceiver. Each electrical switch may further include internal switching circuitry for routing electrical signals within the electrical switch.

High-capacity optical switch assemblies switch multiple channels of data at high data rates, with the number of channels reaching several hundreds and data rates reaching hundreds of Gb/s (Gb/s=109 bits per second). In order to save power, it is desirable to co-package the switch itself with “optical engines,” which typically are small, high-density optical transceivers located within an application-specific integrated circuit (ASIC) or within an ASIC package together with the switch.

The switch assembly is contained in a rack-mounted case, with optical receptacles on its front panel for ease of access. The signals from and to the ASIC are conveyed to and from the optical receptacles using optical fibers.

To further simplify installation and use, it is sometimes desirable that the optical cable be detachable from the transceivers so that a smaller cable may be routed through an installation. Each optical cable may, instead of comprising a transceiver, be designed to mate with a particular transceiver. The transceiver may be connected to a node, such as a server, and be used to connect a connector of each cable to the node as described herein.

In embodiments, the optical switch assembly may comprise one or more processing circuits; the processing circuits may comprise FW.

Optical switches are one solution for enabling advances in networking due to the technology's potential for very high data capacity and low power consumption. Optical switches feature optical input and output ports and are capable of routing light that is coupled to the input ports to the intended output ports on demand, according to one or more control signals (electrical or optical control signals). Routing of the signals is performed in the optical domain, i.e. without the need for optical-electrical and electrical-optical conversion, thus bypassing the need for power-consuming transceivers. Header processing and buffering of the data is not possible in the optical domain and thus, packet switching (as it is realized in electrical switches) cannot be employed. Instead, the circuit switching paradigm is used: an end-to-end circuit is created for the communication between two endpoints connected on the input and the output of the optical switch. Director switches may be used in the most common datacenter interconnection topologies, e.g., fat trees, Slim Fly, and Dragonfly+).

An optical switch may include hardware and/or software for routing signals in the optical domain. Thus, in one embodiment, an optical switch may include input optical fibers and output optical fibers that carry optical signals as well as one or more devices suited for routing optical signals within the optical switch. For example, the one or more devices for routing optical signals may include one or more movable mirrors (e.g., MEMS mirrors) that are controlled to move in a manner that directs light from an input fiber to a desired output fiber or to move in a manner that forces or guides light from one waveguide into another waveguide. An optical switch may include one or more devices for amplifying light in order to compensate for propagation and scattering losses introduced by the optical switch. In at least one example embodiment, signals input and output to an ASIC are optical, meaning that each optical switch connected to an electrical switch routes optical signals received from the electrical switch without using hardware and/or software that converts an electrical signal into an optical signal for routing within the optical switch. However, example embodiments are not limited thereto, and an optical switch may include electrical to optical to electrical conversion hardware and/or software if desired (e.g., if the input signal and/or output signal is an electrical signal).

In an embodiment, the optical switch(es) may include an arrayed waveguide grating router (AWGR), which is a passive switch fabric. In some embodiments, the optical switch(es) may correspond to a passive element that operates as a wavelength router that uses multiple wavelengths to interconnect outputs and inputs by following a specific cyclic wavelength routing pattern.

An optical switch, on the other hand, may function by directly routing optical signals without converting them to electrical signals. Each optical switch may include optical receivers, such as photodetectors and wavelength-division multiplexing (WDM) demultiplexers, that receive incoming optical signals. These optical signals may then be directed through internal optical switching components, such as micro-electromechanical systems (MEMS) mirrors, waveguides, or optical cross-connects, which route the signals to the appropriate output paths. The optical switch may also include optical transmitters, such as laser diodes and modulators, which transmit the routed optical signals to the next switch in the network. A hybrid electro-optical switch may combine both electrical and optical components to route signals. Such a switch may include receivers that convert optical signals into electrical signals using TIAs and photodetectors, similar to those in electrical switches. These electrical signals can then be routed within the switch using internal electrical switching circuitry.

Additionally, the hybrid switch may contain optical switching components, such as WDM multiplexers and MEMS devices, to route optical signals directly. The transmitters in a hybrid switch may include both electrical-to-optical converters and direct optical transmitters, enabling the hybrid switch to interface with both electrical and optical networks. For example, a hybrid switch's transmitter may include a light source, a modulator for optical signals, and traditional electrical signal transmitters, providing routing capabilities across different signal domains.

The interconnections between the switches within the network topology may be implemented via optical fibers or traditional electrical cables, depending on the specific requirements of the system. For instance, the communication lanes may be constructed of dedicated differential cable pairs and/or fiber optics, each tailored to provide optimal performance for the data transmission needs. The dedicated differential cable pairs used in these interconnections may include a variety of cable media such as copper, aluminum, gold, silver, nickel, or composite materials like copper-clad aluminum, copper-clad steel, or bimetallic conductors. These materials may be chosen for their electrical conductivity and durability, ensuring reliable and efficient data transmission. For example, in a four-lane network, each lane may consist of its own dedicated copper cable, providing isolated physical paths for each communication lane of a deserialized data stream. This configuration helps in maintaining signal integrity and reducing crosstalk between lanes.

Alternatively, fiber optic cables may be employed for the interconnections. Fiber optics are capable of transmitting data streams via different wavelengths of light, with each data stream assigned a unique wavelength. The use of fiber optic cables may allow multiple data streams to be transmitted simultaneously through a single fiber optic cable, significantly increasing the bandwidth and efficiency of the network, and particularly advantageous for long-distance data transmission and for applications requiring high data transfer rates. Various optical networking technologies can be used to transmit multiple optical signals (e.g., data signals or data streams) over a single optical fiber within an optical link with little to no optical signal interference. These technologies may be used to improve bandwidth efficiency and reduce the amount of infrastructure needed for data communication.

One such technology is Time Division Multiplexing (TDM). In TDM, multiple optical signals can be transmitted over a single optical fiber by assigning each optical signal a respective time slot and transmitting an optical signal during its assigned time slot. The time slots are allocated in a cyclic manner, with each optical signal transmitting a small amount of data during its assigned time slot. The time slots are very short, on the order of microseconds, and the cycle repeats many times per second, allowing for rapid data transfer.

Another technology is Frequency Division Multiplexing (FDM). In FDM, multiple optical signals can be transmitted over a single optical fiber by assigning each optical signal a respective frequency band. Each optical signal is modulated onto a respective carrier frequency to generate a modulated signal, and these modulated signals are combined and transmitted over a single optical fiber. At the receiver, the modulated signals are separated using filters (e.g., band-pass filters) that permit optical signals meeting specific frequency specifications to pass through while filtering out other signals. FDM allows optical links to simultaneously transmit multiple channels over the same frequency band.

Yet another technology is Wavelength Division Multiplexing (WDM). In WDM, multiple optical signals having different wavelengths are combined into a single optical signal and transmitted over a single optical fiber. WDM techniques involve combining and separating multiple optical signals with different wavelengths onto a single optical fiber, allowing for more data to be transmitted and increasing the capacity of the optical fiber.

Examples of WDM technology include Coarse Wavelength Division Multiplexing (CWDM) and Dense Wavelength Division Multiplexing (DWDM). CWDM combines multiple optical signals at different wavelengths into a single optical signal and transmits it over a single optical fiber. CWDM uses a wider wavelength separation, such as about 80 nanometers (nm), which means it supports fewer channels and has lower power budgets, making it suitable for shorter distances, up to about 80 kilometers (km). CWDM requires less complex equipment and lower-cost optical components, making it a cost-effective solution for applications that do not require dense wavelength separation. In contrast, DWDM uses narrower wavelength separation, such as about 0.8 nm, allowing for higher channel capacity and longer distances, but typically at a higher cost and complexity.

In at least one embodiment, the techniques described herein are practiced in an active cable. An active cable may sometimes be referred to as a smart cable, intelligent cable, or using other similar nomenclature. An active cable may include circuitry to perform functions such as signal processing, conversion between transmission formats, conversion between transmission media (such as between electrical and optical transmission media), and so forth. In at least one embodiment, an active cable comprises circuitry for collecting telemetry data and analyzing the data using a machine learning model as described herein. The active cable may further comprise one or more general-purpose or specialized processors for using a machine learning model to obtain an inference of a network traffic pattern and respond to the inference.

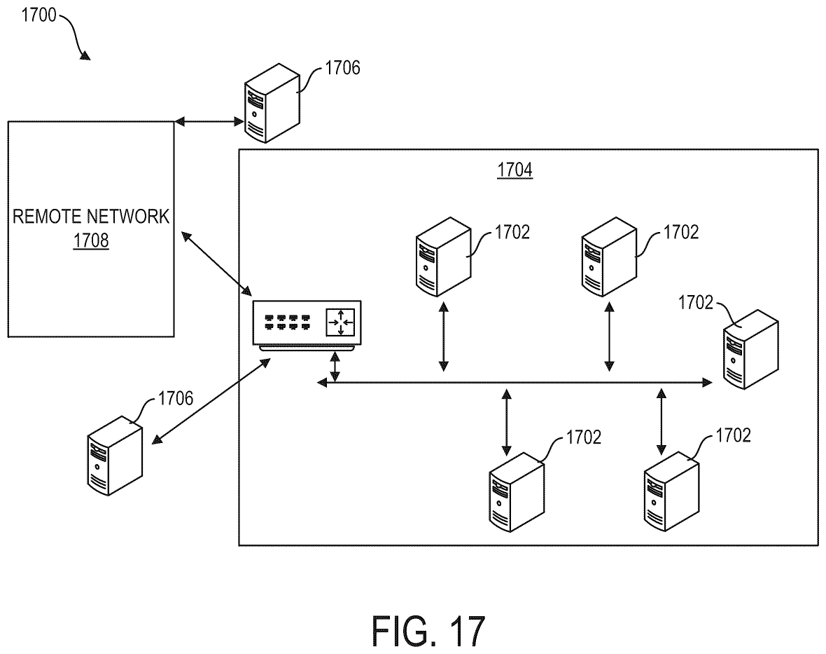

FIG. 17 illustrates a client-server network 1704 formed by a plurality of network server computers 1702 which are interlinked, in accordance with at least one embodiment. In at least one embodiment, each network server computer 1702 stores data accessible to other network server computers 1702 and to client computers 1706 and networks 1708 which link into a wide area network 1704. In at least one embodiment, configuration of a client-server network 1704 may change over time as client computers 1706 and one or more networks 1708 connect and disconnect from a network 1704, and as one or more trunk line server computers 1702 are added or removed from a network 1704. In at least one embodiment, when a client computer 1706 and a network 1708 are connected with network server computers 1702, client-server network includes such client computer 1706 and network 1708. In at least one embodiment, the term computer includes any device or machine capable of accepting data, applying prescribed processes to data, and supplying results of processes.

In at least one embodiment, client-server network 1704 stores information which is accessible to network server computers 1702, remote networks 1708 and client computers 1706. In at least one embodiment, network server computers 1702 are formed by main frame computers minicomputers, and/or microcomputers having one or more processors each. In at least one embodiment, server computers 1702 are linked together by wired and/or wireless transfer media, such as conductive wire, fiber optic cable, and/or microwave transmission media, satellite transmission media or other conductive, optic or electromagnetic wave transmission media. In at least one embodiment, client computers 1706 access a network server computer 1702 by a similar wired or a wireless transfer medium. In at least one embodiment, a client computer 1706 may link into a client-server network 1704 using a modem and a standard telephone communication network. In at least one embodiment, alternative carrier systems such as cable and satellite communication systems also may be used to link into client-server network 1704. In at least one embodiment, other private or time-shared carrier systems may be used. In at least one embodiment, network 1704 is a global information network, such as the Internet. In at least one embodiment, network is a private intranet using similar protocols as the Internet, but with added security measures and restricted access controls. In at least one embodiment, network 1704 is a private, or semi-private network using proprietary communication protocols.

In at least one embodiment, client computer 1706 is any end user computer, and may also be a mainframe computer, mini-computer or microcomputer having one or more microprocessors. In at least one embodiment, server computer 1702 may at times function as a client computer accessing another server computer 1702. In at least one embodiment, remote network 1708 may be a local area network, a network added into a wide area network through an independent service provider (ISP) for the Internet, or another group of computers interconnected by wired or wireless transfer media having a configuration which is either fixed or changing over time. In at least one embodiment, client computers 1706 may link into and access a network 1704 independently or through a remote network 1708.

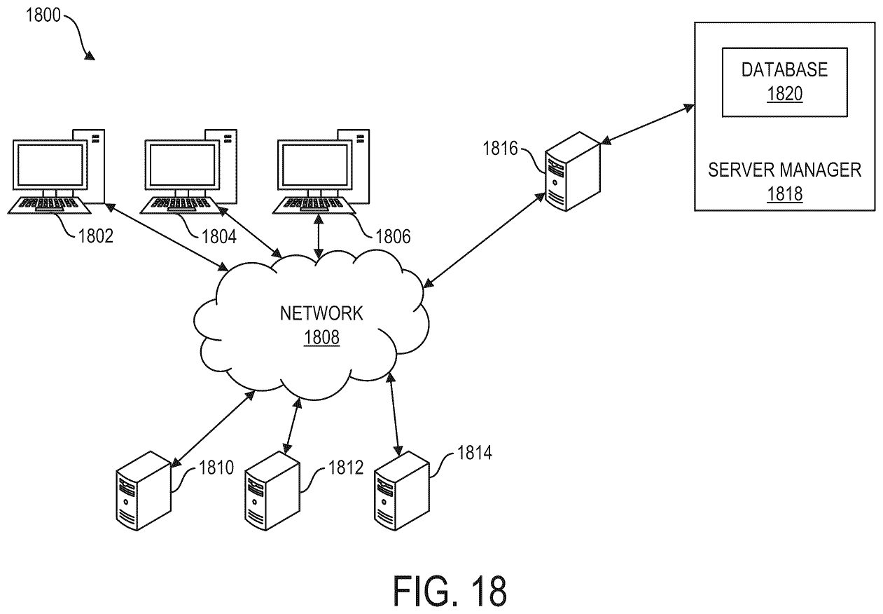

FIG. 18 illustrates a computer network 1808 connecting one or more computing machines, in accordance with at least one embodiment. In at least one embodiment, network 1808 may be any type of electronically connected group of computers including, for instance, the following networks: Internet, Intranet, Local Area Networks (LAN), Wide Area Networks (WAN) or an interconnected combination of these network types. In at least one embodiment, connectivity within a network 1808 may be a remote modem, Ethernet (IEEE 802.3), Token Ring (IEEE 802.5), Fiber Distributed Datalink Interface (FDDI), Asynchronous Transfer Mode (ATM), or any other communication protocol. In at least one embodiment, computing devices linked to a network may be desktop, server, portable, handheld, set-top box, personal digital assistant (PDA), a terminal, or any other desired type or configuration. In at least one embodiment, depending on their functionality, network connected devices may vary widely in processing power, internal memory, and other performance aspects. In at least one embodiment, communications within a network and to or from computing devices connected to a network may be either wired or wireless. In at least one embodiment, network 1808 may include, at least in part, the world-wide public Internet which generally connects a plurality of users in accordance with a client-server model in accordance with a transmission control protocol/internet protocol (TCP/IP) specification. In at least one embodiment, client-server network is a dominant model for communicating between two computers. In at least one embodiment, a client computer (“client”) issues one or more commands to a server computer (“server”). In at least one embodiment, server fulfills client commands by accessing available network resources and returning information to a client pursuant to client commands. In at least one embodiment, client computer systems and network resources resident on network servers are assigned a network address for identification during communications between elements of a network. In at least one embodiment, communications from other network connected systems to servers will include a network address of a relevant server/network resource as part of communication so that an appropriate destination of a data/request is identified as a recipient. In at least one embodiment, when a network 1808 comprises the global Internet, a network address is an IP address in a TCP/IP format which may, at least in part, route data to an e-mail account, a website, or other Internet tool resident on a server. In at least one embodiment, information and services which are resident on network servers may be available to a web browser of a client computer through a domain name (e.g., www.site.com) which maps to an IP address of a network server.

In at least one embodiment, a plurality of clients 1802, 1804, and 1806 are connected to a network 1808 via respective communication links. In at least one embodiment, each of these clients may access a network 1808 via any desired form of communication, such as via a dial-up modem connection, cable link, a digital subscriber line (DSL), wireless or satellite link, or any other form of communication. In at least one embodiment, each client may communicate using any machine that is compatible with a network 1808, such as a personal computer (PC), work station, dedicated terminal, personal data assistant (PDA), or other similar equipment. In at least one embodiment, clients 1802, 1804, and 1806 may or may not be located in a same geographical area.

In at least one embodiment, a plurality of servers 1810, 1812, and 1814 are connected to a network 1808 to serve clients that are in communication with a network 1808. In at least one embodiment, each server is typically a powerful computer or device that manages network resources and responds to client commands. In at least one embodiment, servers include computer readable data storage media such as hard disk drives and RAM memory that store program instructions and data. In at least one embodiment, servers 1810, 1812, 1814 run application programs that respond to client commands. In at least one embodiment, server 1810 may run a web server application for responding to client requests for HTML pages and may also run a mail server application for receiving and routing electronic mail. In at least one embodiment, other application programs, such as an FTP server or a media server for streaming audio/video data to clients may also be running on a server 1810. In at least one embodiment, different servers may be dedicated to performing different tasks. In at least one embodiment, server 1810 may be a dedicated web server that manages resources relating to web sites for various users, whereas a server 1812 may be dedicated to provide electronic mail (email) management. In at least one embodiment, other servers may be dedicated for media (audio, video, etc.), file transfer protocol (FTP), or a combination of any two or more services that are typically available or provided over a network. In at least one embodiment, each server may be in a location that is the same as or different from that of other servers. In at least one embodiment, there may be multiple servers that perform mirrored tasks for users, thereby relieving congestion or minimizing traffic directed to and from a single server. In at least one embodiment, servers 1810, 1812, 1814 are under control of a web hosting provider in a business of maintaining and delivering third party content over a network 1808.

In at least one embodiment, web hosting providers deliver services to two different types of clients. In at least one embodiment, one type, which may be referred to as a browser, requests content from servers 1810, 1812, 1814 such as web pages, email messages, video clips, etc. In at least one embodiment, a second type, which may be referred to as a user, hires a web hosting provider to maintain a network resource such as a web site, and to make it available to browsers. In at least one embodiment, users contract with a web hosting provider to make memory space, processor capacity, and communication bandwidth available for their desired network resource in accordance with an amount of server resources a user desires to utilize.

In at least one embodiment, in order for a web hosting provider to provide services for both of these clients, application programs which manage a network resources hosted by servers must be properly configured. In at least one embodiment, program configuration process involves defining a set of parameters which control, at least in part, an application program's response to browser requests and which also define, at least in part, a server resources available to a particular user.

In one embodiment, an intranet server 1816 is in communication with a network 1808 via a communication link. In at least one embodiment, intranet server 1816 is in communication with a server manager 1818. In at least one embodiment, server manager 1818 comprises a database of an application program configuration parameters which are being utilized in servers 1810, 1812, 1814. In at least one embodiment, users modify a database 1820 via an intranet 1816, and a server manager 1818 interacts with servers 1810, 1812, 1814 to modify application program parameters so that they match a content of a database. In at least one embodiment, a user logs onto an intranet server 1816 by connecting to an intranet 1816 via computer 1802 and entering authentication information, such as a username and password.

In at least one embodiment, when a user wishes to sign up for new service or modify an existing service, an intranet server 1816 authenticates a user and provides a user with an interactive screen display/control panel that allows a user to access configuration parameters for a particular application program. In at least one embodiment, a user is presented with a number of modifiable text boxes that describe aspects of a configuration of a user's web site or other network resource. In at least one embodiment, if a user desires to increase memory space reserved on a server for its web site, a user is provided with a field in which a user specifies a desired memory space. In at least one embodiment, in response to receiving this information, an intranet server 1816 updates a database 1820. In at least one embodiment, server manager 1818 forwards this information to an appropriate server, and a new parameter is used during application program operation. In at least one embodiment, an intranet server 1816 is configured to provide users with access to configuration parameters of hosted network resources (e.g., web pages, email, FTP sites, media sites, etc.), for which a user has contracted with a web hosting service provider.

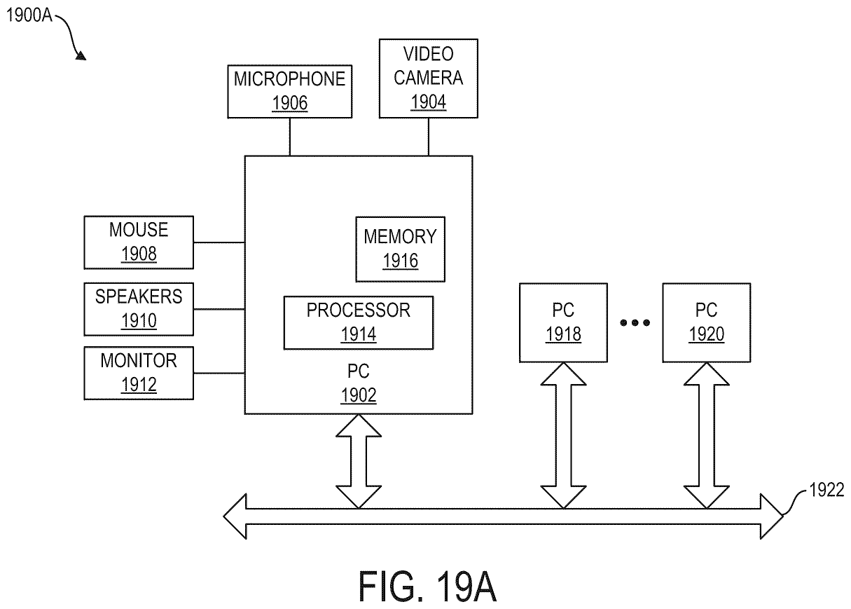

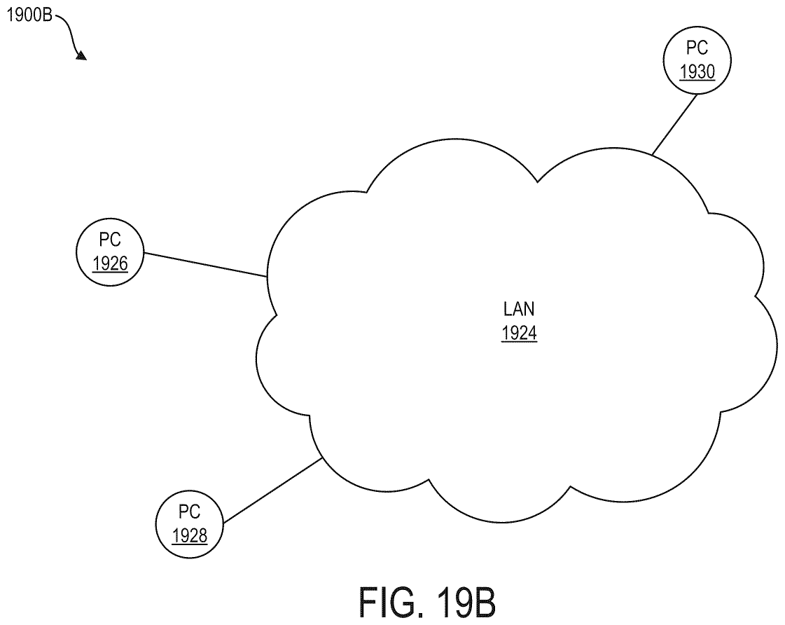

FIG. 19A illustrates a networked computer system 1900A, in accordance with at least one embodiment. In at least one embodiment, networked computer system 1900A comprises a plurality of nodes or personal computers (“PCs”) 1902, 1918, 1920. In at least one embodiment, personal computer or node 1902 comprises a processor 1914, memory 1916, video camera 1904, microphone 1906, mouse 1908, speakers 1910, and monitor 1912. In at least one embodiment, PCs 1902, 1918, 1920 may each run one or more desktop servers of an internal network within a given company, for instance, or may be servers of a general network not limited to a specific environment. In at least one embodiment, there is one server per PC node of a network, so that each PC node of a network represents a particular network server, having a particular network URL address. In at least one embodiment, each server defaults to a default web page for that server's user, which may itself contain embedded URLs pointing to further subpages of that user on that server, or to other servers or pages on other servers on a network.

In at least one embodiment, nodes 1902, 1918, 1920 and other nodes of a network are interconnected via medium 1922. In at least one embodiment, medium 1922 may be, a communication channel such as an Integrated Services Digital Network (“ISDN”). In at least one embodiment, various nodes of a networked computer system may be connected through a variety of communication media, including local area networks (“LANs”), plain-old telephone lines (“POTS”), sometimes referred to as public switched telephone networks (“PSTN”), and/or variations thereof. In at least one embodiment, various nodes of a network may also constitute computer system users inter-connected via a network such as the Internet. In at least one embodiment, each server on a network (running from a particular node of a network at a given instance) has a unique address or identification within a network, which may be specifiable in terms of an URL.

In at least one embodiment, a plurality of multi-point conferencing units (“MCUs”) may thus be utilized to transmit data to and from various nodes or “endpoints” of a conferencing system. In at least one embodiment, nodes and/or MCUs may be interconnected via an ISDN link or through a local area network (“LAN”), in addition to various other communications media such as nodes connected through the Internet. In at least one embodiment, nodes of a conferencing system may, in general, be connected directly to a communications medium such as a LAN or through an MCU, and that a conferencing system may comprise other nodes or elements such as routers, servers, and/or variations thereof.

In at least one embodiment, processor 1914 is a general-purpose programmable processor. In at least one embodiment, processors of nodes of networked computer system 1900A may also be special-purpose video processors. In at least one embodiment, various peripherals and components of a node such as those of node 1902 may vary from those of other nodes. In at least one embodiment, node 1918 and node 1920 may be configured identically to or differently than node 1902. In at least one embodiment, a node may be implemented on any suitable computer system in addition to PC systems.

FIG. 19B illustrates a networked computer system 1900B, in accordance with at least one embodiment. In at least one embodiment, system 1900B illustrates a network such as LAN 1924, which may be used to interconnect a variety of nodes that may communicate with each other. In at least one embodiment, attached to LAN 1924 are a plurality of nodes such as PC nodes 1926, 1928, 1930. In at least one embodiment, a node may also be connected to the LAN via a network server or other means. In at least one embodiment, system 1900B comprises other types of nodes or elements, for example including routers, servers, and nodes.

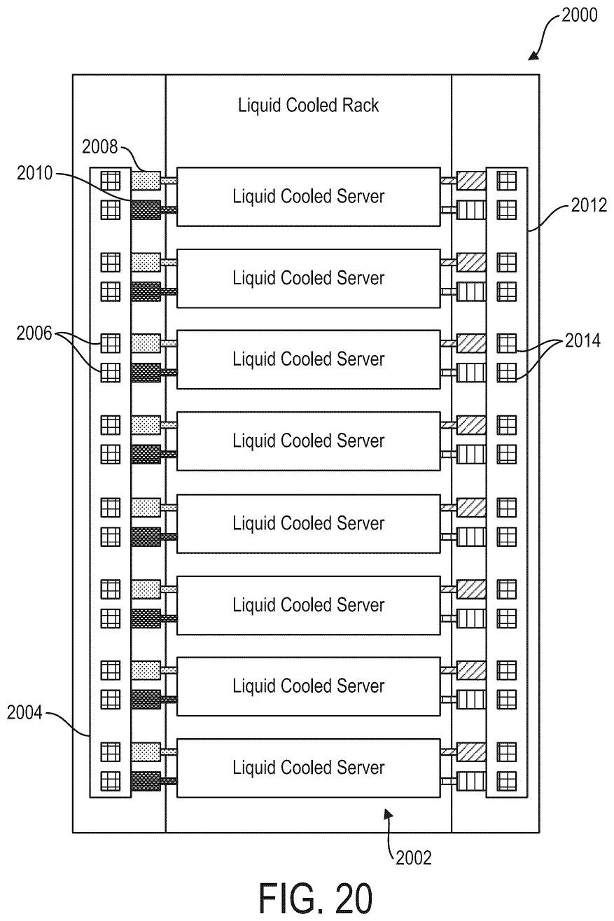

In at least one embodiment, neural networks can be embedded in various devices to enable those devices to predict future state, and make proactive adjustments based at least in part upon those predictions. In at least one embodiment, this can include neural network enabled devices to be installed directly in a liquid cooled server rack 2000 as illustrated in FIG. 20. In at least one embodiment, rack 2000 can include a number of liquid cooled servers 2002 or other such devices. In at least one embodiment, a neural network enabled rack manifold 2004 can be included in rack 2000 to provide a flow of liquid into each liquid cooled server 2002 through an inlet value 2008, and return liquid with heat removed from that server 2002 through an outlet value 2010. In at least one embodiment, rack manifold 2004 can include a number of neural network-enabled secondary liquid distribution control boards 2006. In at least one embodiment, there can be one such control board 2006 for each inlet valve 2008 and outlet valve 2010 for each server. In at least one embodiment, rack 2000 can also include a neural network-enabled rack power distribution unit (PDU) 2012, which can include multiple outlets designed to distribute electric power to computers or networking equipment within rack 2000. In at least one embodiment, there can be a neural network-enabled power distribution control board 2014 associated with each outlet of PDU 2012. In at least one embodiment, sensors can capture information about temperature, air flow, or other such aspects of a computing environment internal and/or external to rack 2000, including internal and/or external to any individual servers 2002 located therein. In at least one embodiment, fluid cooling can remove an amount of heat from servers 2002, but due to factors such as varying load and external temperature fluctuations, temperatures at various locations may change, and may reach or exceed temperature limits at which these devices can continue to operate correctly. In at least one embodiment, an attempt can be made to ensure that temperatures at specific locations remain below an acceptable limit, where those locations may relate to junction temperatures or core temperatures for a processor (e.g., a CPU or GPU), memory module, or power supply.

In at least one embodiment, neural networks in these control boards 2006, 2014 can be tasked to predict values such as coolant flow or air flow, as well as temperatures at these various locations at one or more future points in time. In at least one embodiment, predictions from these networks can be used by a respective board, manifold, PDU, or other such device to make adjustments to ensure appropriate temperature and flow and keep this equipment functioning properly. In at least one embodiment, these adjustments can include adjusting an amount of heat transfer fluid or air flowing into, or out of, a server or device, as well as a temperature of that fluid or air. In at least one embodiment, this may also include adjusting an amount of power supplied to one or more of these devices. In at least one embodiment, these can include similar adjustments as would be made in other data centers, but can be made based on future predictions instead of observed states, enabling such a system to be proactive instead of reactive. In at least one embodiment, this monitoring can occur continually or at least at regular intervals, in order to ensure proper continued operation.

In at least one embodiment, each neural network in each type of component can be trained specifically for that type of component, and can receive updated network parameters that may be generated as a result of further training or continued learning. In at least one embodiment, inferences generated by individual devices can be shared with other devices in a data center as well, which can help to make more accurate predictions. In at least one embodiment, each control board 2006, 2014 can be a neural network enabled board, ASIC, or other such component. In at least one embodiment, a control board can have components of a general purpose computer, including at least one processor and memory with associated circuitry. In at least one embodiment, a Jetson board from NVIDIA Corporation can be used that is a complete system-on-module (SPM), with CPU, GPU, PMIC, DRAM, and flash storage included therein. In at least one embodiment, such a module is also extensible to provide additional functionality or capabilities. In at least one embodiment, each such board can function as a small artificial intelligence (AI) or machine learning enabled computer. In at least one embodiment, multiple such boards can be used in parallel, such as on rack manifold 2004, in order to concurrently process data from multiple high-resolution sensors. In at least one embodiment, these various neural networks can make predictions that can be shared across servers, a rack, or a data center, for example, in order to provide accurate predictions for various locations at one or more future points in time. In at least one embodiment, appropriate adjustments can then be made as appropriate in order to maintain temperatures and other parameters at appropriate levels or values. In at least one embodiment, a liquid distribution control board 2006 may make predictions that can be used to adjust only controls for a relevant flow value, or may share these predictions so that other adjustments can be made as well based at least in part upon these predictions. In at least one embodiment, a control system for a data center may collect predictions from these various boards or networks in order to make adjustments that are more appropriate for an overall data center. In at least one embodiment, adjustments can then be made at a server, rack, pod, data center, or other such level.

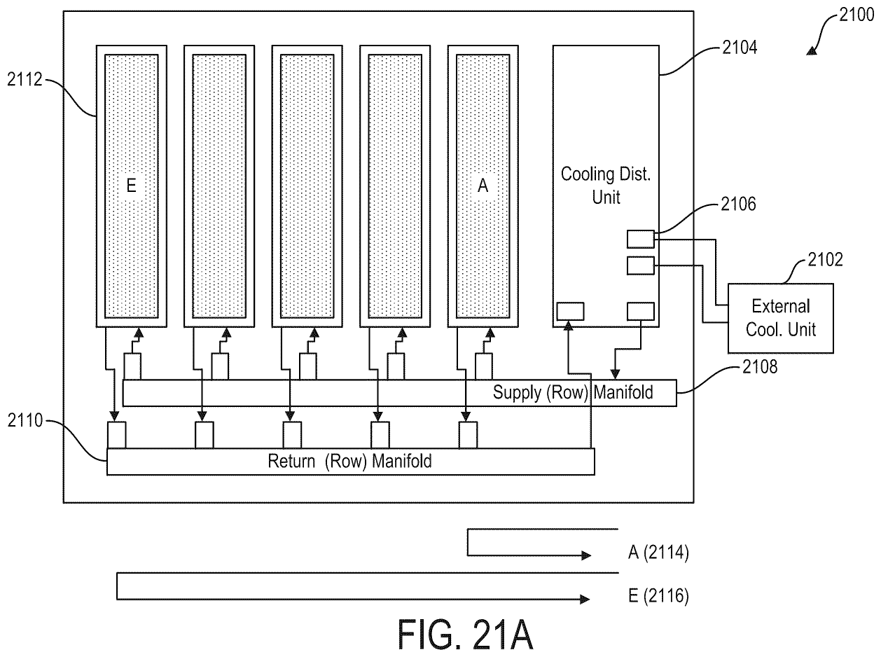

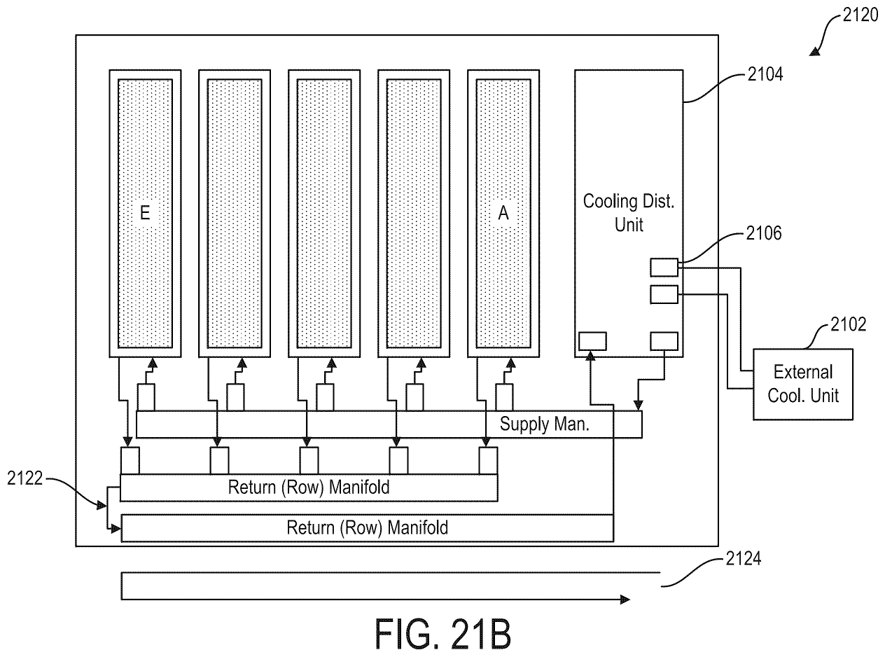

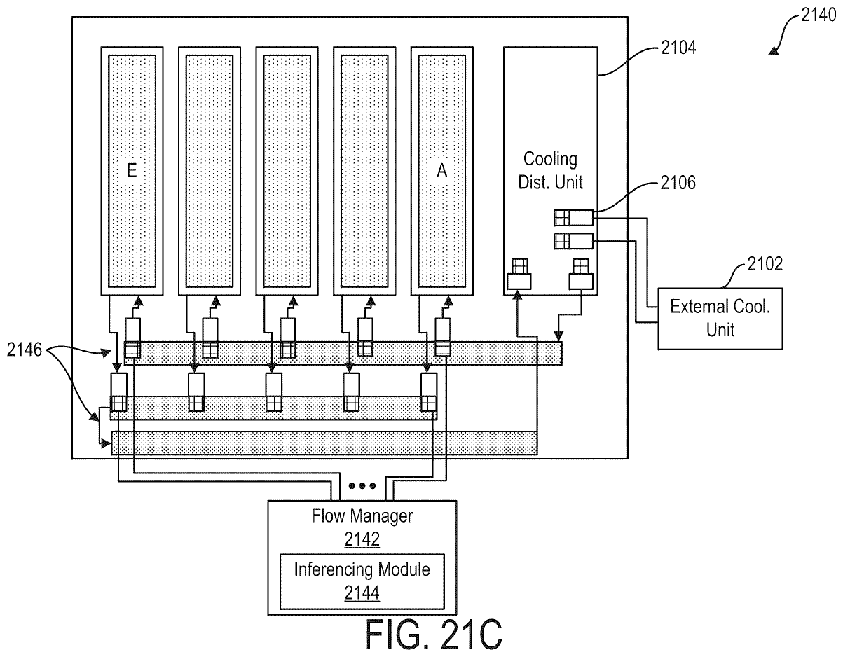

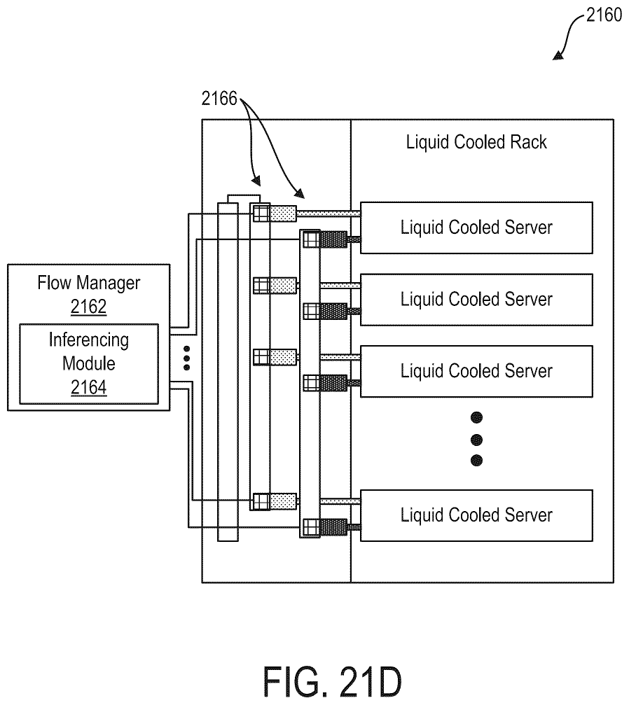

In at least one embodiment, a neural network-enabled approach to liquid cooling of racks at a data center level can utilize components of a system 2100 illustrated in FIG. 21A. In at least one embodiment, an external cooling unit 2102 can provide liquid at a determined temperature to a data center cooling distribution unit 2104. In at least one embodiment, this unit 2104 can include a set of neural network-enabled distribution unit control boards 2106, which can perform inferencing and make adjustments based upon inferred future values. In at least one embodiment, this can include adjusting a temperature of liquid to be received from external cooling unit 2102, or adjusting a flow of that liquid to and/or from that external unit 2102. In at least one embodiment, this can also include adjusting flow into a manifold 2108 for a row of liquid cooled racks 2112, as well as flow into and out of those racks, as may be determined based at least in part upon inferences from neural network-enabled control boards 2110 built into row manifold 2110. In at least one embodiment, there can be different levels of flow into, and out of, different liquid cooled racks. In at least one embodiment, there may also be different flows into individual servers in a rack, such as is described with respect to FIG. 20. In at least one embodiment, a similar approach can be used for an air-cooled data center. In at least one embodiment, temperature and air flow can be measured and predictions made for future values, at times such as 30 seconds, one minute, five minutes, or an hour into our future, which can then enable adjustments to be made to air temperature, air flow, power distribution, and other such aspects. In at least one embodiment, these predictions can be made using various types of input data, such as server load, current temperature, current pressure, flow rate, power consumption, and other pertinent data for various locations within that data center.

In at least one embodiment, these neural network-enabled boards can control an amount of liquid flow, supply, and return at various locations, such as at a rack, server, or GPU-level. In at least one embodiment, these boards can be used to predict, control, and create an optimal solution for such a data center to maintain desired operating conditions, with no loss of equipment or downtime due to temperature issues or thermal events. In at least one embodiment, this can be based on current and anticipated load, as well as measured or detected network conditions. In at least one embodiment, this approach can be applied to other types of devices as well, as may include UPS power supplies. In at least one embodiment, any device with a logic board or component can have this small neural network code injected for these and other such purposes. In at least one embodiment, such a network can tap into all equipment available in a unit or device, such that in a device such as a PDU a board can adjust or cut power completely to a server node, such as where a leak is detected or predicted and relevant equipment may be subject to damage if operation continues. In at least one embodiment, operation can be terminated, or power shut down, gracefully in order to avoid damage. In at least one embodiment, executing programs may instead be terminated in order to at least avoid a loss of data.

In at least one embodiment, a cooling system can utilize a direct return design, as illustrated in FIG. 21A. In at least one embodiment, coolant from a CDU 2104 is directed along a supply manifold 2108 into individual server racks. In at least one embodiment, a first server rack (A) will receive liquid first along this flow, and a last server rack (E) will receive liquid last along this flow. In at least one embodiment, a return manifold 2110 will be used to receive heated liquid passing from these racks and return that heated liquid to CDU 2104. In at least one embodiment, heated liquid returned from first server rack (A) will have a shortest return path, with last server rack (E) having a longest return path. In at least one embodiment, this results in an overall liquid path 2114 for first server rack (A) that is much shorter than an overall liquid path 2116 for last server rack (E) 2116. In at least one embodiment, there can be significant variation is aspects such as pressure and flow throughout a loop of a cooling system. In at least one embodiment, this may include lower pressure near ends of a cooling loop and higher pressure in a middle portion of that loop. In at least one embodiment, such an imbalanced design can result in unacceptable variation in flow rate across a data center or other environment as different path lengths will result in different pressures, temperatures, and other environmental aspects impacting those flows. In at least one embodiment, different amounts of time needed for this liquid to travel along these different paths can also lead to flow variation.

In at least one embodiment, a reverse return-based design can be utilized as illustrated for system 2120 of FIG. 21B. In at least one embodiment, this system includes a reverse return manifold 2122 that receives heated liquid from first server rack (A) first and last server rack (E) last, but instead of directing that flow back directly to CDU 2106 causes liquid to pass from first to last server, or right to left in FIG. 21B, then back through a second portion to CDU 2104. As illustrated, liquid for each server rack will follow a path of similar length 2124, at least through respective manifolds. In at least one embodiment these path lengths may effectively be equal, allowing for slight variations based upon factors such as placement and component type. In at least one embodiment, liquid for each server rack will flow through essentially an entire length of this supply manifold and this return manifold, instead of different portions as in a direct return design of Fig. 21A. In at least one embodiment, this can cause liquid for all server racks to go through these same variations in temperature, pressure, and other environmental parameters encountered throughout a full run of this manifold. In at least one embodiment, such a balanced design can help to reduce variation in flow rate for liquid delivered to different locations throughout this cooling system. In at least one embodiment, this can help to ensure that flow variation is maintained within a desired range, or less than a maximum variation threshold. In at least one embodiment, such a balanced design can help to ensure equal and sufficient liquid is delivered to all servers and racks in a data center by respective cooling components of a liquid cooling system.

In at least one embodiment, all supply and return fluid lines between one or more CDUs and one or more direct-to-chip (D2C) cold plates cooling loops or heat exchangers in an immersive liquid cooled blade can utilize a reverse return, as opposed to a direct return, in various data center collectors, row manifolds, and rack manifolds. In at least one embodiment, electronic valve controls at each of outlets from these collectors, row manifolds, and rack manifolds can have an ability to both monitor and control a flow of primary and/or secondary heat transfer fluids to, and from, these CDUs leading to cold plates attached to components, such as CPUs, GPUs, and switches, as well as other D2C liquid cooled components and blade immersion servers. In at least one embodiment, a liquid cooling system can utilize a combination of a self-balancing flow design in all primary and secondary loops, along with electronic monitoring and control utilizing AI or machine learning, based at least in part upon data received from various flow rate, pressure, temperature, power, and other environmental or operational sensors. In at least one embodiment, such an approach can provide for improved or optimized liquid distribution liquid cooled components, such as servers and processors, in environments such as data centers.

In at least one embodiment, neural network-based flow control can be used with such a design to provide for further variation minimization or flow consistency. In at least one embodiment, a combination of self balancing along with electronics monitoring and control can provide for very balanced and optimized flow of coolant to each of server, rack, processor, or other such component without these components fighting each other and without requiring extensive control schemes. In at least one embodiment, flow controllers can be located at various locations throughout a cooling system, such as may be used to direct coolant into, and out of, components such as racks, servers, and electronic components, where that liquid can be provided using pathways such as row and rack manifolds. In at least one embodiment, these flow controllers can allow for incremental control (e.g., partial opening and closing) to provide for an accurate, self-balancing approach. In at least one embodiment, a self-balancing design with fine adjustable control can provide for accurate balancing of liquid flow across various, if not all, outlets of a liquid cooling system. In at least one embodiment, such an approach can be used to provide a flow of, for example, 50 liters per minute (lpm) with a tolerance, threshold, or variation range of +/−5 lpm, whereas a design without such an approach might have a flow of around 60 1pm at one location and around 40 lpm at another due to differences such as pressure gradients and gravitational effects, which can be an unacceptable flow imbalance across a system.

In at least one embodiment, a control system 2140 can be implemented as illustrated in FIG. 21C. In at least one embodiment, a reverse return row manifold design can be utilized to provide for a balance of pressure and flow across this system. In at least one embodiment, controllable flow valves 2146 can be used at various inlet and/or outlet locations, such a inlets and outlets to individual racks from a row manifold. In at least one embodiment, a flow manager 2142 can receive data from various sensors, devices, or data sources across a relevant environment. In at least one embodiment, this flow manager 2142 can provide at least some of this data as input to one or more neural networks (e.g., deep neural networks (DNNs)) of an inferencing module 2144. In at least one embodiment, sensors and valves can be calibrated for a type of heat transfer fluid utilized. In at least one embodiment, there may be one flow manager 2142 for an entire data center or environment, or there can be flow managers for individual rows, racks, or servers. In at least one embodiment, neural networks can be utilized at each individual flow control valve as well, as may communicate with one or more separate flow controllers. In at least one embodiment, flow manager 2142 can receive one or more inferences from inferencing module 2144, where those inferences may include adjustments or settings for individual flow control valves. In at least one embodiment, flow manager 2142 can then send this or related data or instructions to these individual flow control valves 2146, or other such components, to make small adjustments to help balance flow across this system.

In at least one embodiment, such an approach can be used at a rack level or server level as well as illustrated in system 2160 of FIG. 21D. In at least one embodiment, a liquid cooled rack can have a rack manifold that utilizes a reverse return design, so that liquid path lengths for individual servers of a rack are equivalent as well. In at least one embodiment, a size of this manifold can be much smaller than a size of a corresponding rack, as FIG. 21D illustrates an exploded view for clarity of explanation. In at least one embodiment, a flow manager 2162 can utilize an inferencing module 2164 to determine adjustments to be made to individual flow control valves 2166 within a rack, to balance flow across individual servers in a rack. In at least one embodiment, a flow manager can provide such instructions to flow control valves or components within a server as well, such as may be used to direct coolant for specific cold plates, processors, or other internal server components. In at least one embodiment, use of these intelligent control valves can provide for well-balanced plumbing distribution and controllability. In at least one embodiment, each of these smart control valves 2166 can marginally adjust itself as appropriate, as may be under direction of a flow manager. In at least one embodiment, these flow valves may utilize PID or PIV servo control, where PIV allows for control based on both position and velocity errors.

In at least one embodiment, one or more neural networks can be trained to infer an amount of liquid cooling needed for various components under various circumstances. In at least one embodiment, this may include determining how much additional cooling may be needed for a GPU that goes to 500 Watts of operational power from a more normal 300 Watts, which may require 1.7 lpm instead of 1.0 lpm. In at least one embodiment, this neural network can infer an adjustment to be made to liquid flow for that component, and can enable an accurate adjustment to be made proactively in order to avoid a significant temperature fluctuation from resulting. In at least one embodiment, there may be one or more tables of operations that may correlate factors such as proportional flow rate with power dissipation, which can be used to train these models or used to determine adjustments based on inferred state data. In at least one embodiment, these tables can also be used for different types of components, or different models of a same type of component, in order to account for differences inherent to these components themselves. In at least one embodiment, inferences can be made at different levels of granularity, from an overall data center level to a level of an internal server component such as a GPU. In at least one embodiment, data can be gathered by a component such as a board management controller (BMC) or a server and provided through a networking port to a flow manager, which can send instructions to one or more flow controllers to make one or more appropriate adjustments.

In at least one embodiment, a neural network can predict fluid state at various locations at one or more future times based at least in part upon available information. In at least one embodiment, this can include a snapshot of current information, or may include at least some data over a recent past. In at least one embodiment, these predictions can then be used to adjust aspects such as flow rate. In at least one embodiment, a cooling distribution unit may adjust a flow of liquid or coolant temperature. In at least one embodiment, such equipment can take these predictions and be proactive in order to prevent any undesirable events before they occur. In at least one embodiment, a variety of sensors may provide information about a current state of a computing environment. In at least one embodiment, this may include use of sensors such as temperature sensors, load sensors, flow sensors, or pressure sensors, which can be instantaneously or historically gathered. In at least one embodiment, predictions made based on data from these sensors may be compared to one or more thresholds, ranges, or other operational criteria to determine whether any changes should be made. In at least one embodiment, this can include making an adjustment to prevent an unacceptable temperature rise at a specific location within a data center or other such environment. In at least one embodiment, this may include closing a valve or increasing an amount of coolant flow, adjusting a coolant temperature, or sounding an alarm, among other such remedial actions.

The term “coupling” or similar language is intended to encompass both direct and indirect connections, whether physical, electrical, mechanical, logical, or otherwise. The connection may involve direct physical contact, attachment, or engagement, or it may involve communication, interaction, or cooperation between the elements. The term coupling to is used broadly to include any form of association, linkage, or relationship that enables the desired functionality or cooperation between two claimed elements. The term “coupled to” is not limited to any specific type of connection and is intended to cover a range of possible configurations and implementations.

Although the operations of the method(s) herein are shown and described in a particular order, the order of the operations of each method may be altered so that certain operations may be performed in an inverse order or so that certain operations may be performed, at least in part, concurrently with other operations. In another embodiment, instructions or sub-operations of distinct operations may be implemented in an intermittent and/or alternating manner.

Alternatively, embodiments of the disclosure may be implemented entirely in hardware or in an implementation containing both hardware and software elements. In embodiments which use software, the software may include but is not limited to firmware, resident software, microcode, etc.

Although specific embodiments of the disclosure have been described and illustrated, the disclosure is not to be limited to the specific forms or arrangements of parts so described and illustrated. The scope of the disclosure is to be defined by the claims appended hereto and their equivalents.

1. A connector comprising:
a stationary interface member coupled to a body structure so that the stationary interface member is stationary with respect to the body structure; and
a piston assembly operatively coupled to the body structure and operatively coupled to the stationary interface member through the body structure, the piston assembly including a piston connected to a coupling member, the piston being positioned in the piston assembly and configured to be displaced in both axial and radial directions with respect to the body structure so that the coupling member can move in the axial and radial directions.

2. The connector of claim 1, wherein the coupling member is a universal quick disconnect (UQD).

3. The connector of claim 1, further comprising a friction-reducing washer positioned between the piston assembly and the body structure so that the piston assembly can move in the radial direction.

4. The connector of claim 1, wherein an elongate portion of the piston is positioned in a piston bore member that is operatively coupled to the body structure, wherein the piston can move in the axial direction relative to the piston bore member.

5. The connector of claim 4, further comprising an O ring on the elongate portion of the piston to provide a seal between the elongate portion of the piston and the piston bore member.

6. The connector of claim 4, further comprising an O ring positioned between the stationary interface member and the piston bore member to provide a seal between the stationary interface member and the piston bore member.

7. The connector of claim 4, further comprising a coil spring positioned between the piston and the piston bore member to move the piston back to a default position after an axial movement.

8. The connector of claim 7, further comprising a friction-reducing washer positioned between the coil spring and the piston so that the piston can move in the radial direction.

9. The connector of claim 1, wherein the stationary interface member is a closing barb with a barb fitting end to connect to a fluid line.

10. A connector connected between a rack and a switch comprising:
a stationary interface member coupled to a body structure so that the stationary interface member is stationary with respect to the body structure, the stationary interface member being connected to the switch;
a piston assembly operatively coupled to the body structure and connected to the stationary interface member through the body structure, the piston assembly including a piston connected to a coupling member that is connected to the rack, the piston being positioned in the piston assembly and configured to be displaced in both axial and radial directions with respect to the body structure, thereby allowing an axial and radial floatation on a rack side of the connector, while staying stationary on a switch side of the connector.

11. The connector of claim 10, wherein the coupling member is a universal quick disconnect (UQD) that is connected to the rack.

12. The connector of claim 10, further comprising a friction-reducing washer positioned between the piston assembly and the body structure so that the piston assembly can move in the radial direction.

13. The connector of claim 10, wherein an elongate portion of the piston is positioned in a piston bore member that is operatively coupled to the body structure, wherein the piston can move in the axial direction relative to the piston bore member.

14. The connector of claim 13, further comprising a coil spring positioned between the piston and the piston bore member to move the piston back to a default position after an axial movement.

15. The connector of claim 14, further comprising a friction-reducing washer positioned between the coil spring and the piston so that the piston can move in the radial direction.

16. The connector of claim 10, wherein the stationary interface member is a closing barb with a barb fitting end to connect to a fluid line in the switch.

17. A liquid-cooled switch comprising:
a housing;
tubing in the housing for transferring coolant; and
a connector with two degrees of freedom, the connector being configured to counteract dependency of motions inside and outside of the switch such that when a part of the connector moves outside of the switch, the tubing in the switch connected to the connector does not move.

18. The liquid-cooled switch of claim 17, wherein the connector includes a coupling member that can move in both axial and radial directions.

19. The liquid-cooled switch of claim 18, wherein the connector includes an interface member that remains stationary when the coupling member moves in the axial and/or radial direction, the interface member being connected to the tubing.

20. The liquid-cooled switch of claim 17, wherein the connector includes a piston and a piston bore member, wherein the piston is configured to move in the axial direction relative to the piston bore member.

21. The liquid-cooled switch of claim 17, wherein the tubing is rigid, flexible, corrugated or welded tubing.
